(19) United States
(12) Patent Application Publication
(10) Pub. No.: US 2026/0015728 A1
(43) Pub. Date: Jan. 15, 2026

(54) SYSTEMS AND METHODS FOR REACTOR APPARATUS CONTROL DURING SEMICONDUCTOR WAFER PROCESSES

(71) Applicant: GlobalWafers Co., Ltd., Hsinchu (TW)

(72) Inventors: Qingmin Liu, Glen Carbon, IL (US); Charles R. Lottes, Ballwin, MO (US); Jeffrey L. Libbert, O'Fallon, MO (US)

(21) Appl. No.: 19/263,979

(22) Filed: Jul. 9, 2025

Related U.S. Application Data
(60) Provisional application No. 63/669,564, filed on Jul. 10, 2024.
(60) Provisional application No. 63/687,378, filed on Aug. 27, 2024.

(51) Int. Cl. C23C 16/52; C30B 25/16; H01L 21/67

(52) U.S. Cl. CPC C23C 16/52; C30B 25/165; H01L 21/67248

(57) ABSTRACT

A method of operating a reactor apparatus during a deposition process includes controlling the reactor apparatus to initiate the deposition process; receiving temperature feedback signals from temperature sensors positioned in respective zones of the reactor apparatus; during each process step of at least two process steps: applying a respective set of offsets to the temperature feedback signals received from the temperature sensors, wherein the set of offsets applied for each process step are predetermined for the respective process step to control a characteristic of the semiconductor wafer following the respective process step; and transmitting power instructions to heating devices each positioned in one of the zones of the reactor apparatus, wherein the power instructions are determined by executing feedback control using the temperature feedback signals with the applied set of offsets and a target temperature for the respective process step.

### CROSS-REFERENCE TO RELATED APPLICATIONS

This application claims the benefit of priority to U.S. Provisional Patent Application No. 63/687,378, filed Aug. 27, 2024, and U.S. Provisional Patent Application No. 63/669,564, filed Jul. 10, 2024, the disclosures of which are incorporated herein by reference in their entirety.

### FIELD

The present disclosure relates generally to the manufacture of semiconductor structures (e.g., semiconductor-on-insulator structures), and more particularly, to systems and methods for controlling a reactor apparatus during a semiconductor wafer process, such as a layer deposition process.

### BACKGROUND

Single crystal silicon, which is a starting material for the fabrication of semiconductor electronic devices (e.g., microelectronic devices), is commonly prepared by growing a single crystal silicon ingot by the Czochralski (“CZ”) method. In this method, polycrystalline silicon is charged to a crucible and melted, a seed crystal is brought into contact with the molten silicon, and a single crystal ingot is grown by slow extraction. Other single crystal growth techniques, such as the float zone method, may also be utilized to produce single crystal silicon ingots. The single crystal silicon ingot is trimmed and ground to have one or more flats or notches for proper crystal orientation in subsequent procedures, and is then sliced into individual single crystal silicon wafers.

Silicon wafers may be utilized in the preparation of layered silicon structures with one or more layers deposited on the silicon wafer to provide certain characteristics or properties that are useful during end device fabrication. For example, silicon wafers are frequently used to prepare silicon-on-insulator (SOI) structures, which facilitate reducing parasitic capacitance and improving performance of the end device. An SOI structure includes a semiconductor handle wafer, a device layer, and an insulator or dielectric layer (e.g., an oxide layer) between the handle wafer and the device layer. The device layer is typically a thin layer of single crystal silicon, transferred to the handle wafer from a silicon donor wafer. The semiconductor handle wafer may be made of single crystal silicon, or other suitable semiconductor materials, such as germanium, silicon carbide, silicon germanium, gallium arsenide, and other alloys of Group III and Group V elements, such as gallium nitride or indium phosphide, or alloys of Group II and Group VI elements, such as cadmium sulfide or zinc oxide.

An SOI structure may be prepared by forming a dielectric layer (e.g., an oxide layer) on a polished front surface of a donor wafer made of single crystal silicon. Particles (e.g., hydrogen ions or a combination of hydrogen and helium ions) are implanted at a specified depth beneath the front surface of the donor wafer and form a cleave plane in the donor wafer at the specified implant depth. The front surface of the donor wafer is then bonded to a handle wafer to form a bonded structure through a hydrophilic bonding process. The handle wafer may additionally or alternatively include the dielectric layer. The donor wafer is thereafter separated (i.e., cleaved) along the cleave plane from the bonded structure to form the SOI structure. The resulting SOI structure includes a thin layer of silicon (the portion of the donor wafer remaining after cleaving) disposed atop the dielectric layer and the handle wafer. The thin layer of silicon forms the device layer of the SOI structure.

SOI structures may be implemented in radiofrequency (RF) related devices such as antenna switches and offer benefits over traditional substrates in terms of cost and integration. High resistivity handle wafers (e.g., handle wafers having a resistivity greater than 500 Ohm-cm, or greater than 1000 Ohm-cm) are frequently used in SOI structures implemented in RF devices to reduce parasitic power loss and minimize harmonic distortion inherent when using conductive substrates for high frequency applications. SOI structures that include a high resistivity handle wafer are prone to formation of high conductivity charge inversion or accumulation layers at the interface of the dielectric layer and the high resistivity handle wafer, causing generation of free carriers (electrons or holes) which reduce the effective resistivity of the handle wafer and give rise to parasitic power losses and device nonlinearity when the devices are operated at RF frequencies. These inversion/accumulation layers can be due to oxide fixed charge, oxide trapped charge, interface trapped charge, and even DC bias applied to the devices themselves.

Charge trapping layers are commonly used to improve the performance of RF devices fabricated using high resistivity SOI structures. The charge trapping layer is positioned between the high resistivity handle wafer and the dielectric layer and acts as a high defectivity layer to trap the charge in any induced inversion or accumulation layers so that the high resistivity of the handle wafer is maintained even near the surface region. Charge trapping layers may include polycrystalline or amorphous semiconductor material (e.g., polycrystalline or amorphous silicon). For example, it has been shown in academic studies that a polycrystalline silicon charge trapping layer in between the oxide layer and the handle wafer improves the device isolation, decreases transmission line losses and reduces harmonic distortions. See, for example: H. S. Gamble, et al. “Low-loss CPW lines on surface stabilized high resistivity silicon,” Microwave Guided Wave Lett., 9(10), pp. 395-397, 1999; D. Lederer, R. Lobet and J.-P. Raskin, “Enhanced high resistivity SOI wafers for RF applications,” IEEE Intl. SOI Conf., pp. 46-47, 2004; D. Lederer and J.-P. Raskin, “New substrate passivation method dedicated to high resistivity SOI wafer fabrication with increased substrate resistivity,” IEEE Electron Device Letters, vol. 26, no. 11, pp. 805-807, 2005; D. Lederer, B. Aspar, C. Laghać and J.-P. Raskin, “Performance of RF passive structures and SOI MOSFETs transferred on a passivated HR SOI substrate,” IEEE International SOI Conference, pp. 29-30, 2006; and Daniel C. Kerr et al. “Identification of RF harmonic distortion on Si substrates and its reduction using a trap-rich layer”, Silicon Monolithic Integrated Circuits in RF Systems, 2008. SIRF 2008 (IEEE Topical Meeting), pp. 151-154, 2008.

In some known methods of manufacturing high resistivity SOI structures, the charge trapping layer is deposited on a front surface of the high resistivity handle wafer (e.g., using chemical vapor deposition). The properties of the charge trapping layer, such as thickness, thickness uniformity, flatness, bow and warp, slip, roughness, trap efficiency, etc., are strongly affected by several key steps of the deposition process. The deposition process must therefore be well-controlled throughout to achieve the desired charge trapping layer properties.

There is an ongoing need for reactor apparatus and methods that facilitate better control of the deposition process to enable depositing charge trapping layers with desired properties. Furthermore, there is a need to facilitate such control of the deposition process implemented across multiple reactor apparatus used to perform the deposition process to ensure consistently and reliably depositing the charge trapping layer in any suitable reactor apparatus.

### BRIEF SUMMARY

One aspect is a method of operating a reactor apparatus during a deposition process for depositing a layer of material on a semiconductor wafer, the deposition process including a first process step and a second process step. The method includes: controlling the reactor apparatus to initiate the deposition process; receiving temperature feedback signals from temperature sensors positioned in respective zones of the reactor apparatus during the deposition process; during the first process step: applying a first set of offsets to the temperature feedback signals received from the temperature sensors, wherein the first set of offsets are predetermined to control a first characteristic of the semiconductor wafer following the first process step; and transmitting first power instructions to heating devices each positioned in one of the zones of the reactor apparatus, wherein the first power instructions are determined by executing feedback control using the temperature feedback signals with the applied first set of offsets and a first target temperature; and during the second process step: applying a second set of offsets to the temperature feedback signals received from the temperature sensors, wherein the second set of offsets are predetermined to control a second characteristic of the semiconductor wafer following the second process step; and transmitting second power instructions to the heating devices, wherein the second power instructions are determined by executing feedback control using the temperature feedback signals with the applied second set of offsets and a second target temperature.

Another aspect is a system for depositing a layer of material on a semiconductor wafer. The system includes a reactor apparatus including: a chamber defining different zones; a temperature sensor positioned in each zone; a heating device positioned in each zone; and a susceptor in the chamber for supporting the semiconductor wafer. The system also includes a controller in communication with the reactor apparatus, the controller configured to: store, in memory, a predetermined recipe for a deposition process including process steps, and target temperatures for the process steps of the deposition process; control the reactor apparatus to initiate the deposition process according to the recipe; receive temperature feedback signals from the temperature sensors of the reactor apparatus during the deposition process; apply offsets stored in the memory to the temperature feedback signals received from the temperature sensors; determine power instructions for the heating devices by executing feedback control using the temperature feedback signals with the applied offsets and the target temperatures; and transmit the power instructions to the heating devices. The offsets stored in the memory include a first set of offsets applied during a first process step of the process steps and a second set of offsets applied during a second process step of the process steps, the first set of offsets being predetermined to control a first characteristic of the semiconductor wafer following the first process step and the second set of offsets being predetermined to control a second characteristic of the semiconductor wafer following the second process step.

Another aspect is a method of preparing a system for performing a deposition process for depositing a layer of material on a semiconductor wafer, the deposition process including a first process step and a second process step, the system including a controller and a reactor apparatus, the controller being configured to control operation of the reactor apparatus by receiving temperature feedback signals from the reactor apparatus, applying offsets to the temperature feedback signals, determining power instructions for heating devices of the reactor apparatus by executing feedback control using the temperature feedback signals with the applied offsets and a set of target temperatures including first and second target temperatures for the first and second process steps, respectively, and transmitting the power instructions to the heating devices. The method includes: performing the first process step of the deposition process on each of a first set of semiconductor wafers using the reactor apparatus,
wherein the controller controls operation of the reactor apparatus during the first process step using a first set of offsets applied to the temperature feedback signals, wherein the first set of offsets is different for each of the first set of semiconductor wafers; measuring a first characteristic of each of the first set of semiconductor wafers following the first process step; identifying one of the first sets of offsets for use in controlling the reactor apparatus based on the measured first characteristics of the first set of semiconductor wafers; performing the second process step of the deposition process on each of a second set of semiconductor wafers using the reactor apparatus, wherein the controller controls operation of the reactor apparatus during the second process step using a second set of offsets applied to the temperature feedback signals, wherein the second set of offsets is different for each of the second set of semiconductor wafers; measuring a second characteristic of each of the second set of semiconductor wafers following the second process step; identifying one of the second sets of offsets for use in controlling the reactor apparatus based on the measured second characteristics of the second set of semiconductor wafers; and storing, in a memory of the controller, the identified first set of offsets for use in controlling the reactor apparatus during the first process step and the identified second set of offsets for use in controlling the reactor apparatus during the second process step.

Advantages and features of the embodiments disclosed herein will be in part apparent and in part pointed out hereinafter.

### BRIEF DESCRIPTION OF THE DRAWINGS

FIG. 1 depicts a semiconductor-on-insulator (SOI) structure, according to embodiments of the present disclosure.

FIG. 2 is an example semiconductor structure used as a handle and/or donor substrate to prepare the SOI structure of FIG. 1.

FIG. 3 depicts one example of a process sequence for preparing the SOI structure of FIG. 1.

FIG. 4 is a diagram of an example of a system that includes a reactor apparatus and a controller.

FIG. 5 is a side view of components included in the reactor apparatus of FIG. 4.

FIG. 6 is a plan view of components included in the reactor apparatus of FIG. 4.

FIG. 7 illustrates a configuration of an example computing device.

FIG. 8 is a diagram of components of one or more example computing devices that may be used in embodiments of the described systems and methods.

FIG. 9 is a flowchart of an example process for controlling process parameters in the reactor apparatus of FIG. 4 to consistently achieve desired properties in a deposited layer of material.

FIG. 10 is a flowchart of an example process of determining offsets (e.g., temperature offsets) and target temperatures to be applied during different process steps of a deposition process performed using a reactor apparatus.

FIG. 11 is a plot of oxide layer thickness vs. offset temperatures for front, side, and rear temperature sensors of a reactor apparatus following a first process step of a deposition process of the present disclosure.

FIG. 12 is a plot of slip count vs. offset temperatures for a temperature sensor of a reactor apparatus following a second process step of a deposition process of the present disclosure.

FIG. 13 is a plot of layer thickness vs. deposition temperature following a deposition process of the present disclosure.

Corresponding reference numerals are used throughout the drawings to indicate corresponding features and elements.

### DETAILED DESCRIPTION

Embodiments of the present disclosure relate to reactor apparatus and related methods for processing semiconductor wafers, for example, semiconductor wafers used in the manufacture of semiconductor-on-insulator structures. In some embodiments, the reactor apparatus and methods of the present disclosure are operable to deposit a layer of material, such as a layer of charge trapping semiconductor material, on a surface of a semiconductor wafer. The reactor apparatus is controlled using a controller that is programmed with a predetermined recipe that is developed to produce the wafer having the desired characteristics when processing in the reactor apparatus is complete. The controller is configured to provide a well-controlled and finely tuned process using the reactor apparatus that appropriately compensates for various process conditions that can be affected by process drift frequently encountered in high volume manufacturing due to discrete variations in components of the reactor. For example, in high volume manufacturing, where multiple reactor apparatus are used to process wafers according to a standard wafering process (e.g., deposition process), temperature variations between the reactor apparatus are frequently encountered and need to be appropriately compensated for to ensure that the desired characteristics of the wafer can be reliably and consistently achieved across multiple reactors. For example, in the context of deposition processes for layers of charge trapping semiconductor material, the temperature variations need to be adequately compensated for, so that all the characteristics of the processed wafer that can be affected by temperature, such as, for example, deposited layer thickness, thickness uniformity, slip, roughness, bow, warp, resistivity, etc. are properly controlled.

In embodiments of the present disclosure, the controller used in conjunction with the reactor apparatus and stores the predetermined recipe for a deposition process performed on a semiconductor wafer. The deposition process includes a first process step and a second process step, and the controller compensates for temperature variations and different characteristics during each of the first and second process steps. In particular, the controller stores a first set of offsets used during the first process step, which are predetermined to control a first characteristic of the wafer following the first process step, and the controller stores a second set of offsets used during the second process step, which are predetermined to control a second characteristic of the wafer following the second process step. The first and second characteristics can vary since they may be affected particularly or discretely during the respective first and second process steps. In this way, the controller is configured to apply different temperature offsets at different stages of the deposition process to continuously compensate for temperature variations while also taking into consideration particular characteristics of the wafer that can be affected during the different stages of the process.

Embodiments of the present disclosure also provide accurate and efficient methods of configuring a controller for operating a reactor apparatus using a predetermined recipe. In particular, embodiments of the present disclosure relate to determining temperature offsets and target temperatures to be applied during different process steps of a deposition process performed using the reactor apparatus, which take into account discrete temperature variations of the particular reactor apparatus and therefore enable consistent and reliable implementation of the predetermined recipe across multiple reactor apparatus. The embodiments provide a significant advancement over conventional methods of configuring controllers with pre-programmed instructions for performing a deposition process within a particular reactor apparatus, which typically involve tuning many parameters independently (e.g., tuning temperature and time for bow, tuning deposition time for thickness target, etc.). These conventional processes are inefficient and time and cost-intensive, since each process condition would affect multiple quality parameters, and each quality parameter can be affected by multiple process conditions. For this reason, configuring the controller for operating a reactor apparatus according to any given wafering process is quite complicated and often takes weeks before the reactor apparatus is ready for production. The present disclosure provides a systematic tuning method that is highly desired for high volume manufacturing.

### Example Semiconductor-on-Insulator (SOI) Structures, and Substrates and Methods for Preparing SOI Structures

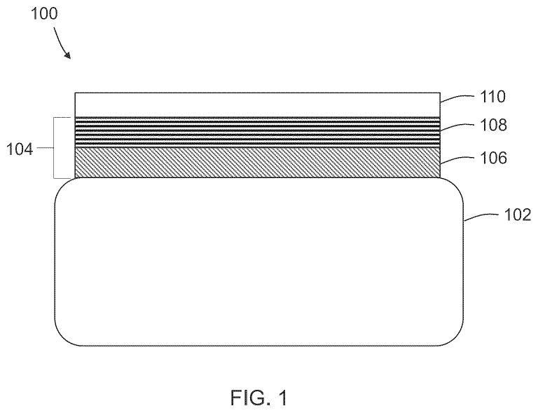

Referring now to the drawings, FIG. 1 depicts a multilayer structure 100 prepared according to embodiments of the present disclosure. The multilayer structure 100 is also referred to as a semiconductor-on-insulator (SOI) structure 100 and, in some embodiments, is a silicon-on-insulator structure. The multilayer structure 100 includes, in stacked succession, a single crystal semiconductor handle substrate 102, an intermediate layer or layers 104, and a device layer 110. The intermediate layer 104 can include one or more dielectric layers 108 (also referred to as an insulating or insulator layer 108, or a buried oxide or BOX layer 108). In some embodiments, the intermediate layer 104 can also include a charge trapping layer 106 between the dielectric layer(s) 108 and the handle substrate 102.

The handle substrate 102 is made of any suitable semiconductor material. In some embodiments, the handle substrate 102 is made of single crystal silicon. In some embodiments, the handle substrate 102 is a single crystal silicon wafer. In various embodiments, the handle substrate 102 is made of a semiconductor material selected from the group consisting of silicon, germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

The handle substrate 102 is a high resistivity substrate in some examples. For example, the handle substrate 102 has a minimum bulk resistivity of at least 500 Ohm-cm, at least 1000 Ohm-cm, or at least 3000 Ohm-cm, such as between 500 Ohm-cm and 100,000 Ohm-cm.

The dielectric layer(s) 108 acts as an electrical insulator layer between the device layer 110 and the handle substrate 102 to minimize or eliminate leakage currents, lower parasitic capacitance, and otherwise improve the performance of the end device. The material used for the dielectric layer 108 varies depending on the intended application of the SOI structure 100 and/or the desired characteristics of the dielectric layer 108. In some embodiments, the dielectric layer 108 includes an oxide and/or a nitride film. In some embodiments, the dielectric layer 108 is in part or in whole a silicon dioxide (SiO₂) film. In various embodiments, the dielectric layer 108 includes a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof. In some embodiments, the dielectric layer 108 is formed of multiple dielectric layers. For example, in some embodiments, the dielectric layer 108 includes a first dielectric layer formed on the charge trapping layer 106 and a second dielectric layer bonded to the first dielectric layer, where the second dielectric layer is formed on a donor wafer from which the device layer 110 is transferred. The dielectric layer 108 has any suitable thickness to enable the dielectric layer 108 to function as described. The thickness of the dielectric layer 108 may vary depending on the intended application of the multilayer structure 100. In various embodiments, the dielectric layer 108 has a thickness between 10 nm to 10 μm, such as between 10 nm to 1 μm.

The charge trapping layer 106 is formed on the handle substrate 102 (e.g., by chemical vapor deposition) and positioned in the multilayer structure 100 between the handle substrate 102 and the dielectric layer 108. The charge trapping layer 106 includes a semiconductor material, such as a polycrystalline or amorphous semiconductor material. The semiconductor material included in the charge trapping layer 106 is suitably capable of forming a highly defective layer between the handle substrate 102 and the dielectric layer 108. In some embodiments, the charge trapping layer 106 includes polycrystalline or amorphous silicon, silicon germanium, silicon carbide, carbon-doped silicon, germanium, and combinations thereof. The term “silicon germanium” includes alloys of silicon and germanium in any molar ratio of silicon and germanium. “The term “polycrystalline” denotes a semiconductor material comprising small semiconductor crystals having random crystal orientations. For example, polycrystalline silicon grains may be as small in size as about 20 nanometers. Smaller crystal grain sizes of polycrystalline semiconductor material may provide higher defectivity in the charge trapping layer 106. The term “amorphous” denotes a semiconductor material that is in non-crystalline allotropic form, which lacks short range and long range order. Silicon grains having crystallinity over no more than about 10 nanometers may also be considered essentially amorphous silicon.

The semiconductor material of the charge trapping layer 106 acts as a high density trap region to prevent and/or kill conductivity in the handle substrate 102 that may otherwise occur at an interface between the handle substrate 102 and the dielectric layer 108. The charge trapping layer 106 also prevents the formation of induced charge inversion or accumulation layers in the multilayer structure 100 that can contribute to power loss and non-linear behavior in electronic devices designed for radiofrequency (RF) device operation. The charge trapping layer 106 has any suitable thickness to enable the charge trapping layer to function as described. The thickness of the charge trapping layer 106 may vary depending on the intended application of the multilayer structure 100. In various embodiments, the charge trapping layer 106 has a thickness between 0.1 μm to 50 μm, such as between 1 μm to 10 μm.

In some embodiments, the charge trapping layer 106 has a resistivity of at least 500 Ohm-cm, at least 1000 Ohm-cm, or at least 3000 Ohm-cm, such as between 500 Ohm-cm to 100,000 Ohm-cm, between 1000 Ohm-cm to 10,000 Ohm-cm, between 2000 Ohm-cm to 10,000 Ohm-cm, between 3000 Ohm-cm to 10,000 Ohm-cm, or between 3000 Ohm cm to 5000 Ohm-cm.

The device layer 110 is the portion of the multilayer structure 100 upon or in which microelectronic devices are formed. In particular, the device layer 110 has an exposed or outer surface, opposite the intermediate layer 104, that defines a top surface of the multilayer structure 100 upon or in which microelectronic devices are formed. In some embodiments, the device layer 110 includes single crystal silicon material, and the multilayer structure 100 is a silicon-on-insulator (SOI) structure having the silicon device layer 110. Thus, the multilayer structure 100 may interchangeably be referred to herein as an SOI structure 100. Although the device layer 110 is described as a silicon layer, the device layer 110 may additionally and/or alternatively include other semiconductor layers or multiple layers including, for example and without limitation, one or more layers of silicon, germanium, gallium arsenide, aluminum nitride, silicon germanium, gallium nitride, and combinations thereof. The device layer 110 has any suitable thickness to enable the device layer to function as described. The thickness of the device layer 110 may vary depending on the intended application of the multilayer structure 100. In various embodiments, the device layer 110 has a thickness between 10 nm to 3 μm, such as between 10 nm to 1 μm, or between 100 nm to 1 μm.

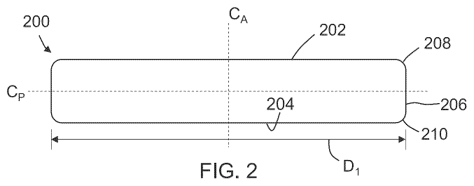

FIG. 2 depicts a single crystal semiconductor substrate 200, also referred to as a substrate 200, that is used in methods of preparing a multilayer structure 100 (FIG. 1) in accordance with embodiments of the present disclosure. In some embodiments, the substrate 200 is used as a semiconductor handle substrate, e.g., a single crystal semiconductor handle wafer. In some embodiments, the substrate 200 may also be used as a semiconductor donor substrate, e.g., a single crystal semiconductor donor wafer, in preparing the multilayer structure 100. As the description proceeds, the terms “substrate” and “wafer” are used interchangeably.

The substrate 200 includes two major, generally parallel surfaces 202, 204. One of the surfaces is a front surface 202 of the substrate 200, and the other surface is a back surface 204 of the substrate 200. The substrate 200 also includes a circumferential edge 206 joining the front surface 202 and the back surface 204. In some embodiments, the substrate 200 includes a beveled peripheral edge 208 extending between the front surface 202 and the circumferential edge 206 and/or a beveled peripheral edge 210 extending between the back surface 204 and the circumferential edge 206. The beveled peripheral edges 208, 210 are shown as being rounded in shape in the illustrated embodiment, but include other shapes in other embodiments (e.g., a chamfer). The beveled peripheral edges 208, 210 are contoured regions (e.g., rounded or chamfered) between the front and back surfaces 202, 204 of the substrate 200 and the circumferential edge 206.

The substrate 200 includes a central plane C_{P} between the front surface 202 and the back surface 204 and an imaginary central axis C_{A} substantially perpendicular to the central plane C_{P}. A radial length of the substrate 200 is measured as the distance between the central axis C_{A} and the circumferential edge 206. A diameter, D₁, of the substrate 200 is measured across the circumferential edge 206. The diameter D₁ varies depending on the intended application of the substrate 200. The diameter D₁ is between 150 millimeters (mm) to 450 mm in various embodiments. In some embodiments, the diameter D₁ is at least 150 mm, at least 200 mm, at least 300 mm, or at least 450 mm. In some embodiments, the diameter D₁ is about 150 mm, about 200 mm, about 300 mm, or about 450 mm.

Prior to any operation as described herein, the front surface 202 and the back surface 204 of the substrate 200 may be substantially identical. The surfaces 202 and 204 are referred to as a “front surface” or a “back surface,” respectively, for convenience and to distinguish the surface upon which subsequent process operations are performed. In the context of the present disclosure, the front surface 202 of the substrate 200 refers to the major surface of the substrate 200 that becomes an interior surface of a semiconductor-on-insulator structure 100 (FIG. 1). In accordance with embodiments described herein, it is with this front surface 202 that the intermediate layer 104 is in interfacial contact. The back surface 204 of the substrate 200 refers to the major surface that is exterior to the stacked succession of layers forming the semiconductor-on-insulator structure 100.

The substrate 200 includes a single crystal semiconductor material suitable for use in semiconductor-on-insulator applications. For example, in various embodiments, the substrate 200 includes a single crystal semiconductor material selected from the group consisting of silicon, germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof. In some embodiments, the substrate 200 includes a single crystal semiconductor material selected from the group consisting of silicon, silicon carbide, silicon germanium, gallium arsenide, gallium nitride, indium phosphide, indium gallium arsenide, germanium, and combinations thereof. In certain embodiments, the substrate 200 includes single crystal silicon.

As described above, the substrate 200 has a diameter D₁ that is, for example, between 150 mm to 450 mm, such as 150 mm or at least 150 mm, 200 mm or at least 200 mm, 300 mm or at least 300 mm, or 450 mm or at least 450 mm. A thickness of the substrate 200, measured between the front and back surfaces 202, 204, varies depending on the intended application of the substrate 200. In various embodiments, the thickness of the substrate is between 250 micrometers (μm) to 1500 μm, such as between 300 μm to 1000 μm, or between 500 μm to 1000 μm. In some specific embodiments, the thickness of the substrate 200 is about 775 μm.

In certain embodiments, the substrate 200 is a single crystal silicon wafer which has been sliced from a single crystal ingot grown in accordance with Czochralski crystal growing methods or float zone growing methods. Such methods, as well as silicon slicing, lapping, etching, and polishing techniques for preparing wafers from the ingots, are disclosed, for example, in F. Shimura, Semiconductor Silicon Crystal Technology, Academic Press, 1989, and Silicon Chemical Etching, (J. Grabmaier ed.) Springer-Verlag, N.Y., 1982, the entire disclosure of which is incorporated by reference herein. Suitably, the wafers are polished and cleaned by methods known to those skilled in the art. See, for example, W. C. O'Mara et al., Handbook of Semiconductor Silicon Technology, Noyes Publications.

The substrate 200 has interstitial oxygen in any suitable concentration that is generally achieved by the CZ or float zone growing methods. For example, the handle substrate may have an interstitial oxygen concentration of between 1×10¹⁶ atoms/cm³ to 5×10¹⁸ atoms/cm³. In some instances, the substrate 200 has a relatively low oxygen content, such as less than 9 nppma or 4.5×10¹⁷ atoms/cm³, less than 6 nppma or 3×10¹⁷ atoms/cm³, less than 5 nppma or 2.5×10¹⁷ atoms/cm³, less than 4 nppma or 2×10¹⁷ atoms/cm³, or less than 3 nppma or 1.5×10¹⁷ atoms/cm³. Interstitial oxygen concentration may be measured according to SEMI MF 1188-1105. Interstitial atomic oxygen concentration (nppma) may be measured according to the New ASTM: ASTM F 121, 1980-1983; DIN 50438/1, 1978.

The substrate 200 has any resistivity obtainable by the CZ or float zone methods. The resistivity of the substrate 200 may vary based on the requirements of the end use/application of the semiconductor-on-insulator structure 100. The resistivity may vary from milliohm or less to megaohm or more. “High resistivity” substrates 200 have a minimum bulk resistivity of at least 500 Ohm-cm, such as between 500 Ohm-cm to 100,000 Ohm-cm. “Low resistivity” substrates 200 have a minimum bulk resistivity of below (less than or equal to) 500 Ohm-cm, such as between 1 Ohm-cm to 100 Ohm-cm. Methods for preparing wafers of varying resistivities are known in the art, and wafers having a desired resistivity may be obtained from commercial suppliers, such as GlobalWafers Co., Ltd., Taiwan.

In some embodiments, the substrate 200 has a relatively high minimum bulk resistivity. High resistivity single crystal semiconductor substrates 200 are generally sliced from single crystal ingots grown by the Czochralski method or float zone method, and may be subjected to a thermal anneal at a temperature ranging from 600° C. to 1000° C. in order to annihilate thermal donors caused by oxygen that are incorporated during crystal growth. In some embodiments, the substrate 200 has a minimum bulk resistivity of at least 500 Ohm-cm, at least 1000 Ohm-cm, or at least 3000 Ohm-cm, such as between 500 Ohm-cm and 100,000 Ohm-cm. Methods for preparing high resistivity wafers are known in the art, and such high resistivity wafers may be obtained from commercial suppliers, such as GlobalWafers Co., Ltd., Taiwan. High resistivity substrates 200 may be used as the handle substrate 102 in an SOI structure 100 intended for use in radio-frequency (RF) devices. High quality RF devices require very high resistivity for good second order harmonic performance (HD2). To maintain the high resistivity of the SOI structure 100 during device fabrication and packaging, the high resistivity substrate 200 may in some examples also include a relatively low interstitial oxygen concentration (e.g., less than 9 nppma, less than 6 nppma, less than 5 nppma, less than 4 nppma, or less than 3 nppma) in order to minimize the thermal donor impact of interstitial and to avoid formation of PN junctions.

In some embodiments, the substrate 200 includes a p-type or an n-type dopant. Suitable p-type dopants include boron, gallium, or combinations thereof. Suitable n-type dopants include phosphorus, antimony, arsenic, or combinations thereof. The dopant concentration in the substrate 200 may be selected based on the desired resistivity of the handle substrate. In some embodiments, the substrate 200 is undoped.

In some embodiments, the substrate 200 is cleaned using an aqueous solution including an oxidizing agent, such as an SC1 and/or an SC2 cleaning solution. In some embodiments, the front surface 202 of the substrate 200 is subjected to a chemical mechanical polishing (“CMP”) operation. A suitable CMP operation involves the immersion of the substrate 200 in an abrasive slurry and polishing the front surface 202 of the substrate 200 using a polymeric pad, whereby through a combination of chemical and mechanical work the front surface 202 is smoothed to a desired surface roughness.

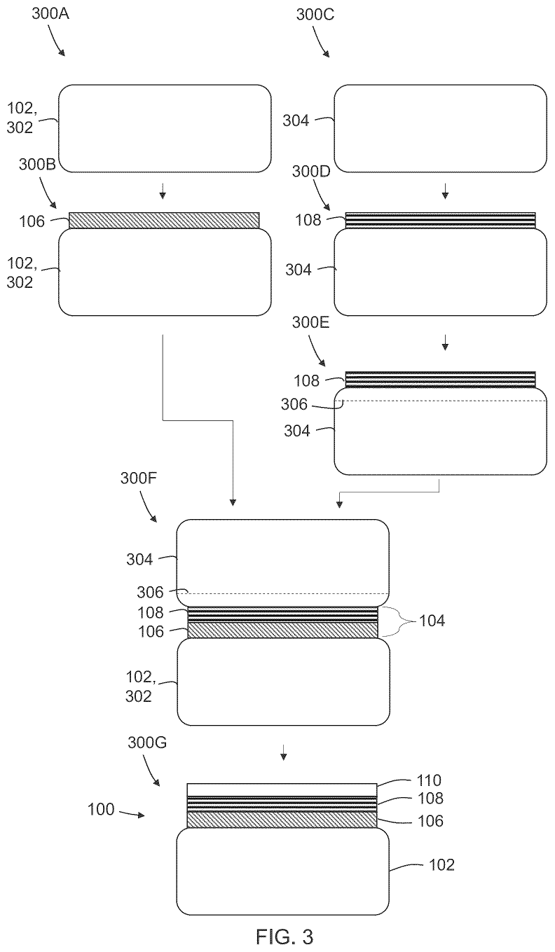

FIG. 3 is an example process flow of forming the SOI structure 100 of FIG. 1. The process begins at step 300A, where a handle substrate 302 is provided, and step 300C, where a donor substrate 304 is provided. The handle substrate 302 is the substrate from which the handle substrate 102 of the SOI structure 100 is derived. The donor substrate 304 is the substrate from which the device layer 110 of the SOI structure 100 is derived. Each of the handle substrate 302 and the donor substrate 304 may include the substrate 200 of FIG. 2.

In various embodiments, the handle substrate 302 and the donor substrate 304 are independently made of single crystal silicon, or other suitable semiconductor materials, such as germanium, silicon carbide, silicon germanium, gallium arsenide, and other alloys of Group III and Group V elements, such as gallium nitride or indium phosphide, or alloys of Group II and Group VI elements, such as cadmium sulfide or zinc oxide. In some embodiments, the handle substrate 302 and the donor substrate 304 independently include a single crystal semiconductor material selected from the group consisting of silicon, silicon carbide, silicon germanium, gallium arsenide, gallium nitride, indium phosphide, indium gallium arsenide, germanium, and combinations thereof. In certain embodiments, each of the handle substrate 302 and the donor substrate 304 includes single crystal silicon.

At least a portion of the intermediate layer 104 (FIG. 1) can be grown on one or both of the handle substrate 302 (step 300B of FIG. 3) or the donor substrate 304 (step 300D of FIG. 3). In this example, at step 300B, the charge trapping layer 106 is grown on the handle substrate using a suitable deposition process, such as a chemical vapor deposition (CVD) process. Suitable methods for depositing the charge trapping layer 106 are described in U.S. Pat. No. 10,283,402, issued May 7, 2019, and U.S. Publication No. 2024/0258155, published Aug. 1, 2024, the disclosures of which are incorporated by reference in their entirety. In some embodiments, the charge trapping layer 106 is deposited using an Epsilon E3000 or E3200 single-wafer epitaxial reactor manufactured by ASM International. Other reactor apparatus suitable for depositing the charge trapping layer 106 include those marketed under the trade name Centura by Applied Materials. Cluster reactor apparatus available from ASM International or Applied Materials can also be suitably used. Suitable reactor apparatus for depositing the charge trapping layer 106 are described in more detail below.

At step 300D, the dielectric layer 108 is grown on the donor substrate 304 by thermal oxidation, CVD oxide deposition, or another suitable technique to grow the dielectric layer 108, such as an oxide film. In some embodiments, the donor substrate 304 is thermally oxidized in a furnace such as an ASM A400 or an ASM A412 to grow the dielectric layer 108. In some embodiments, the dielectric layer 108 is additionally or alternatively grown on the handle substrate 302 (e.g., after depositing the charge trapping layer 106). In some embodiments, a dielectric layer 108 is grown on each of the donor substrate 304 and the handle substrate 304.

Still referring to FIG. 3, the semiconductor device layer 110 in the SOI structure 100 shown in FIG. 1 is derived from the donor substrate 304. The donor substrate 304 is bonded to the handle substrate 302 (step 300F), with the intermediate layer 104 positioned between the bonded substrates 302, 304, and a portion of the donor substrate 304 is removed from the bonded structure to thereby transfer the device layer 110 and the dielectric layer 108 onto the handle substrate 102 and form the SOI structure 100 (step 300G). The device layer 110 and dielectric layer 108 may be transferred onto the handle substrate 302 by wafer thinning techniques such as etching the donor substrate 304 or by cleaving the donor substrate 304 at a cleave plane 306 (formed at step 300E).

In the example process of FIG. 3, at step 300E, the cleave plane 306 is formed in the donor substrate 304 by particle or ion implantation techniques. Particle or ion implantation is suitably carried out in a commercially available instrument, such as an Applied Materials Quantum H. Implanted particles or ions include He, H, H₂, or combinations thereof. Particles or ion implantation is carried out at a density and duration sufficient to form the cleave plane in the donor substrate. Implant density may range from 10¹² ions/cm² to 10¹⁷ ions/cm², such as from 10¹⁴ ions/cm² to 10¹⁷ ions/cm². Implant energies may range from 1 keV to 3,000 keV, such as from 5 keV to 3,000 keV. The depth of implantation determines, at least in part, the thickness of the device layer 110 in the final SOI structure 100 (shown in FIG. 1). In some embodiments, ion implantation is performed after formation of the dielectric layer 108 on the front surface of the donor substrate 304. In some embodiments, the donor substrate 304 is subjected to a cleaning operation after the implant at step 300E. A suitable clean includes a Piranha clean followed by a deionized water rinse and/or cleaning using a SC1 and/or SC2 solution.

In some embodiments, the donor substrate 304 having been subjected to helium ion and/or hydrogen ion implant is annealed at a temperature sufficient to form a thermally activated cleave plane 306 in the donor substrate 304. An example of a suitable tool includes a Box furnace, such as a Blue M model. In some embodiments, the ion implanted donor substrate 304 is annealed at a temperature of from 200° C. to 350° C. Thermal annealing may occur for a duration of from 2 hours to 10 hours. Thermal annealing within these temperatures ranges is sufficient to form a thermally activated cleave plane 305. After the thermal anneal to activate the cleave plane 306, the front surface and/or back surfaces of the donor substrate 304 may be cleaned using cleaning operations described above.

In some embodiments, the bonding surfaces of the donor substrate 304 and the handle substrate 302 are activated prior to bonding (step 300F). In some embodiments, the oxygen plasma surface activation tool is a commercially available tool, such as those available from EV Group, such as EVG® 810LT Low Temp Plasma Activation System. Oxygen plasma surface oxidation is performed in order to render a bonding surface of the donor substrate 304 and/or the handle substrate 302 hydrophilic and amenable to bonding.

Still referring to FIG. 3, at step 300F, the optionally plasma activated bonding surfaces of the donor substrate 304 and the handle substrate 302 are next brought into intimate contact to thereby form a bonded structure. In the illustrated embodiment, the bonded structure includes the dielectric layer 108, e.g., a buried oxide layer, of the donor substrate 304 in interfacial contact with the charge trapping layer 106 of the handle substrate 302. In other embodiments, two dielectric layers 108, one on each of the donor substrate 304 and the handle substrate 302, may be in interfacial contact in the bonded structure.

At step 300F, since the mechanical bond between the handle substrate 302 and the donor substrate 304 may be relatively weak, the bonded structure can be further annealed to solidify the bond. In some embodiments, the bonded structure is annealed at a temperature sufficient to strengthen the bond and form a thermally activated cleave plane 306 in the donor substrate 304. An example of a suitable tool might be a Box furnace, such as a Blue M model. In some embodiments, the bonded structure is annealed at a temperature of from 200° C. to 350° C. Thermal annealing may occur for a duration of from 0.5 hours to 10 hours.

After the bonding and, optionally, thermal anneal to strengthen the bond, the bonded structure is cleaved at step 300G in FIG. 3. The bonded structure is cleaved at the cleave plane 306 to produce the final SOI structure 100 (also shown in FIG. 1) that includes the handle substrate 102, the intermediate layer 104 (here, the charge trapping layer 106 and the dielectric layer 108), and the device layer 110. Alternatively, a portion of the donor substrate may be removed using another suitable layer transfer or wafer thinning technique to form the final SOI structure 100, such as grinding or back-side etching.

Cleaving the bonded structure is performed according to techniques known in the art. In some embodiments, mechanical cleaving is used. In some embodiments, the bonded structure is placed in a conventional cleave station affixed to stationary suction cups on one side and affixed by additional suction cups on a hinged arm on the other side. A crack is initiated near the suction cup attachment and the movable arm pivots about the hinge cleaving the donor substrate apart at the cleave plane 306. Cleaving removes a portion of the donor substrate 304, thereby transferring the device layer 110 (e.g., a silicon device layer) on the SOI structure 100.

After transfer of the device layer 110 (e.g., by cleave), the SOI structure 100 may be subjected to post-layer transfer processing to smooth the outer surface of the device layer 110. For example, after layer transfer, the SOI structure 100 may be subjected to a high temperature anneal, which may also strengthen the bonds between adjacent layers of the SOI structure 100. The high temperature anneal may be performed on multiple SOI structures 100 in a batch furnace to reduce costs, but may be performed on an individual SOI structure 100 in a single wafer processing chamber. An example of a suitable tool for the high temperature anneal is a vertical furnace, such as an ASM A400 or an ASM A412. The high temperature anneal is suitably performed at a temperature and for a duration sufficient to smooth a surface of the device layer 110 and/or strengthen the bonds between adjacent layers in the SOI structure 100. In some embodiments, the SOI structure 100 is annealed at a temperature of greater than or equal to 950° C., such as between 1000° C. to 1200° C., and for a duration of between 15 minutes to 10 hours. The high temperature anneal of the SOI structure 100 may, in some embodiments, be performed in the presence of an anneal atmosphere that includes at least one of an inert gas (e.g., argon gas), hydrogen (H₂) gas, and helium gas, or a combination of two or more of these gases. For example, the high temperature anneal may be performed at a temperature of between 1000° C. to 1200° C., for a duration of between 2 hours to 4 hours, in the presence of argon gas. The high temperature anneal may additionally and/or alternatively be performed in an “active” gas environment, for example, in the presence of nitrogen (N₂) gas, oxygen (O₂) gas, or a combination of N₂ and O₂ gas. A high temperature anneal in an active gas environment may be performed to strengthen the bonds between adjacent layers of the SOI structure 100, but typically will not smooth surfaces of the SOI structure 100 (e.g., the outer surface of the device layer 110).

In some embodiments, the SOI structure 100 may be subjected to post-layer transfer smoothing operations in addition to or in the alternative to the high temperature anneal. For example, a polishing operation, such as CMP, may be performed on the SOI structure 100 to planarize one or both of the exposed surfaces of the SOI structure (e.g., the outer surface of the transferred device layer 110). The polishing operation may be performed in addition to (e.g., before and/or after) or in the alternative to the high temperature thermal anneal. For example, a CMP operation may be performed on the transferred device layer 110, followed by the high temperature thermal anneal performed on the SOI structure 100. However, in some embodiments, a CMP operation is omitted.

Additionally or alternatively, the SOI structure 100 is subjected to a non-contact smoothing process, also referred to as epitaxial smoothing or “epi-smoothing,” after the high temperature anneal and/or the polishing operation. The epi-smoothing process may further reduce the roughness of the outer surface of the device layer 110 on the SOI structure 100 and/or remove any implant damage of the device layer 110 that was not compensated for by any previous smoothing processes (e.g., in the high temperature thermal anneal and/or the polishing operation). Example epi-smoothing processes are described, for example, in U.S. Pat. No. 9,202,711, issued Dec. 1, 2015, the disclosure of which is hereby incorporated by reference herein in its entirety. The epi-smoothing process is typically performed in a suitable reactor (e.g., an epitaxial deposition reactor) that is operable to heat the SOI structure 100 in a reaction chamber and introduce etchant gases into the reaction chamber that perform work on (e.g., etch) the transferred device layer 110 to further smooth the outer surface. For example, the epi-smoothing process may include positioning the SOI structure 100 in an epi-reactor chamber, heating the chamber to a temperature between 900° C. and 1100° C., introducing gaseous etchant (e.g., hydrogen chloride, HCl, or chlorine and hydrogen gas, H₂) into the chamber, and maintaining temperature and flow of the gaseous etchant for a suitable duration to achieve a targeted surface roughness of the transferred device layer 110.

After smoothing, the device layer 110 has a suitable thickness for device fabrication. The SOI structure 100 may subsequently be subjected to further processing based on an intended application or use of the SOI structure. For example, an epitaxial layer may be deposited on the outer surface of the transferred device layer 110. An epitaxial layer deposited on the device layer 110 may include substantially the same electrical characteristics as the underlying device layer. Alternatively, the epitaxial layer deposited on the device layer 110 may include different electrical characteristics as the underlying device layer. An epitaxial layer may comprise a material selected from the group consisting of silicon, silicon carbide, silicon germanium, gallium arsenide, gallium nitride, indium phosphide, indium gallium arsenide, germanium, and combinations thereof. An example of epitaxial reactor apparatus suitable for the epitaxial processing of the device layer 110 is an Epsilon E3000 or E3200 single-wafer epitaxial reactor manufactured by ASM International. Other suitable reactor apparatus include those marketed under the trade name Centura by Applied Materials. In embodiments where epi-smoothing is performed on the SOI structure 100, the SOI structure may remain in the reactor and be subjected to an epi-deposition process in the same reactor, or the epitaxial layer may be deposited on the device layer 110 in a separate reactor. Depending upon the desired properties of the final device, the epitaxial layer may comprise a dopant, such as one or more p-type dopants (e.g., boron, gallium, aluminum, and/or indium) and/or one or more n-type dopants (e.g., phosphorus, antimony, and/or arsenic). The final SOI structure 100 may additionally and/or alternatively be subjected to end of line metrology inspections and cleaned a final time using typical SC1/SC2 process. Oxidation may further be performed on one or more exposed surfaces of the SOI structure 100 for reducing bow or warp of the structure 100.

### Example Reactor Apparatus and Deposition Processes for Preparing SOI Substrates

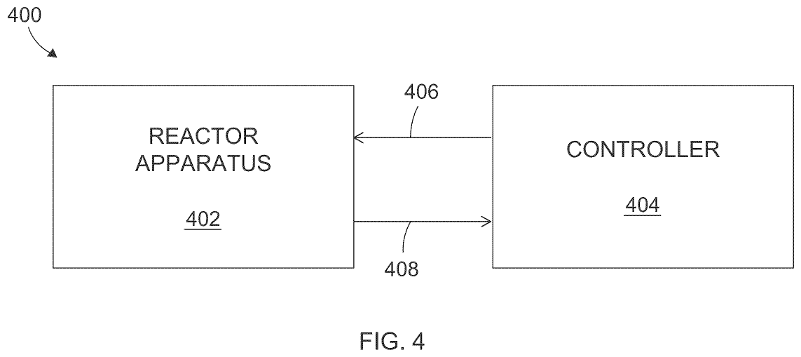

FIG. 4 is a diagram of a system 400 that includes a reactor apparatus 402 and a controller 404. The reactor apparatus 402 in this example is an epitaxial reactor that is used to deposit one or more layers on a semiconductor substrate, such as the semiconductor substrate 200, during a process for preparing an SOI structure, such as the process shown in FIG. 3 for preparing the SOI structure 100. For example, the reactor apparatus 402 is used to deposit the charge trapping layer 106. Examples of epitaxial reactor apparatus that are used as the reactor apparatus 402 include, but are not limited to including, Epsilon E3000 or E3200 single-wafer epitaxial reactors manufactured by ASM International, epitaxial reactors marketed under the trade name Centura by Applied Materials, and cluster reactor apparatus available from ASM International or Applied Materials. The reactor apparatus 402 can also be used in processing semiconductor wafers in implementations other than SOI, such as, for example, processing epitaxial wafers.

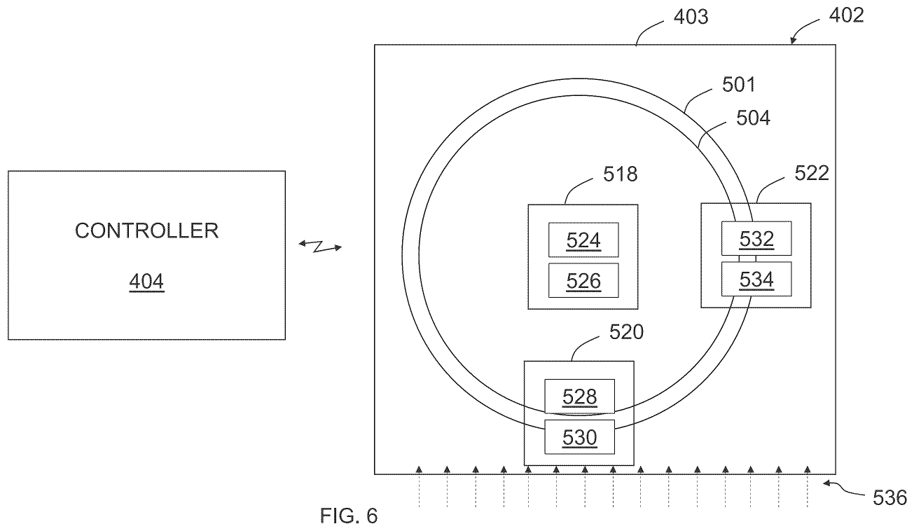

The controller 404 is communicatively coupled to the reactor apparatus 402 to transmit instructions 406 and receive data 408 for use in controlling process parameters (e.g., temperatures, duration, process gas flow rate and composition, susceptor rotation) in the reactor apparatus 402. For example, the controller 404 transmits instructions 406, such as output power instructions for heating devices 526, 530, 534 (FIG. 6) in the reactor apparatus 402. The reactor apparatus 402 transmits data 408, such as temperature measurements obtained using temperature sensors 524, 528, 532 (FIG. 6) in the reactor apparatus 402, to the controller 404 as feedback. The transmission of the instructions 406 to the reactor apparatus 402 and the data 408 from the reactor apparatus 402 enables the controller 404 to determine the appropriate output power instructions to bring zones 518, 520, 522 of the reactor apparatus 402 to a target temperature set point. The target temperature set point used by the controller 404 for controlling each zone depends on the process step being performed in the reactor apparatus 402. Additionally, as described below, the target temperature set point used by the controller 404 for each zone compensates for any power or temperature offset in the respective zone that could otherwise negatively affect process step being performed in the reactor apparatus 402.

Although a single controller 404 is shown and described, the controller 404 may include multiple controllers 404 that may be centralized or decentralized.

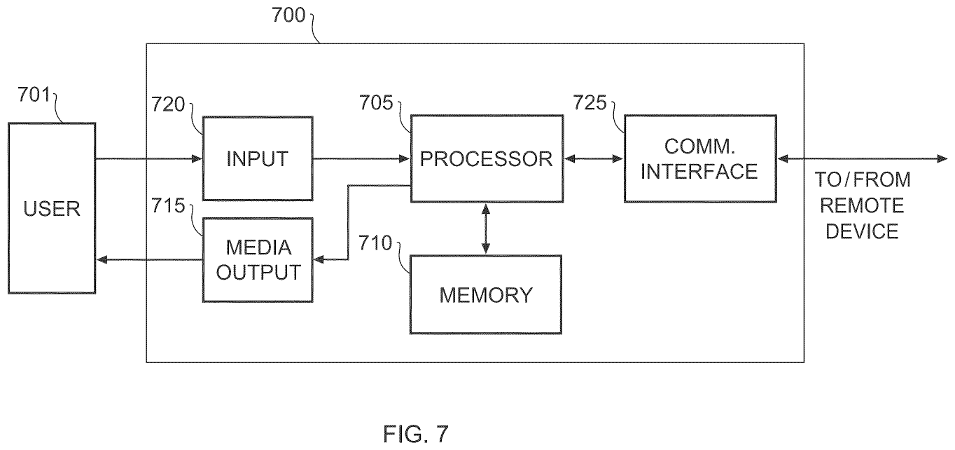

The controller 404 is a computing device, and includes a configuration that may be similar to the configuration depicted in FIG. 7, which illustrates a configuration of a computing device 700 representative of an example of the controller 404. The computing device 700 includes a processor 705 for executing instructions. In some embodiments, executable instructions are stored in a memory area 710. The processor 705 may include one or more processing units (e.g., in a multi-core configuration). The memory area 710 is any device allowing information such as executable instructions and/or data to be stored and retrieved. The memory area 710 may include one or more computer readable storage device or other computer readable media, including transitory and non-transitory computer readable media.

The computing device 700 also includes at least one media output component 715 for presenting information to user 701. The media output component 715 is any component capable of conveying information to the user 701. In some embodiments, the media output component 715 includes an output adapter such as a video adapter and/or an audio adapter. An output adapter is operatively coupled to the processor 705 and operatively couplable to an output device such as a display device (e.g., a liquid crystal display (LCD), organic light emitting diode (OLED) display, cathode ray tube (CRT), or “electronic ink” display) or an audio output device (e.g., a speaker or headphones). In some embodiments, at least one such display device and/or audio device is included in the media output component 715. The computing device 700 also includes an input device 720 for receiving input from the user 701. The input device 720 may include, for example, a keyboard, a pointing device, a mouse, a stylus, a touch sensitive panel (e.g., a touch pad or a touch screen), a gyroscope, an accelerometer, a position detector, or an audio input device. A single component such as a touch screen may function as both an output device of media output component 715 and input device 720. The computing device 700 also includes a communication interface 725, which may be communicatively coupled to a remote computing device. The communication interface 725 may include, for example, a wired or wireless network adapter or a wireless data transceiver for use with a mobile phone network (e.g., Global System for Mobile communications (GSM), 3G, 4G or Bluetooth) or other mobile data network (e.g., Worldwide Interoperability for Microwave Access (WIMAX)).

Stored in the memory area 710 of the computing device 700 are, for example, processor-executable instructions for providing a user interface to the user 701 via the media output component 715 and, optionally, receiving and processing input from the input device 720. The memory area 710 may include, but is not limited to, any computer-operated hardware suitable for storing and/or retrieving processor-executable instructions and/or data. The memory area 710 may include random access memory (RAM) such as dynamic RAM (DRAM) or static RAM (SRAM), read-only memory (ROM), erasable programmable read-only memory (EPROM), electrically erasable programmable read-only memory (EEPROM), and non-volatile RAM (NVRAM). Further, the memory area 710 may include multiple storage units such as hard disks or solid state disks in a redundant array of inexpensive disks (RAID) configuration. The memory area 710 may include a storage area network (SAN) and/or a network attached storage (NAS) system. In some embodiments, the memory area 710 includes memory that is integrated in the computing device 700. For example, the computing device 700 may include one or more hard disk drives as the memory 710. The memory area 710 may also include memory that is external to the computing device 700 and may be accessed by a plurality of computing devices. The above memory types are exemplary only, and are thus not limiting as to the types of memory usable for storage of processor-executable instructions and/or data.

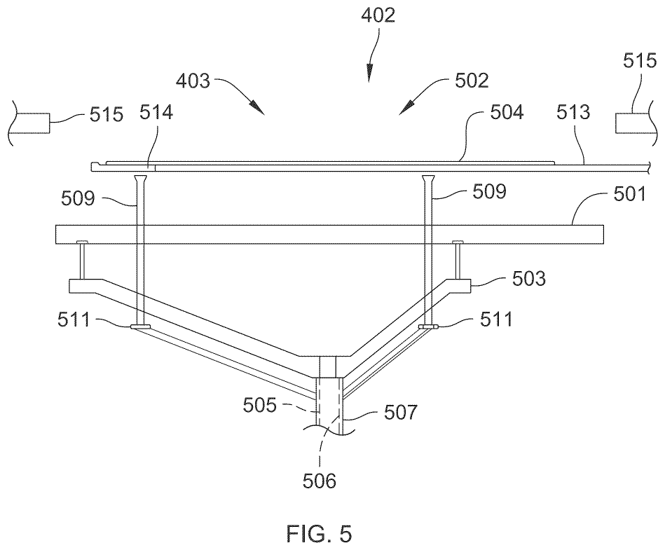

FIG. 5 is a partial section of the reactor apparatus 402 and schematically depicts components included in reactor apparatus 402. A positioning mechanism 502 within the reactor apparatus 402 operates to position a semiconductor wafer 504 (e.g., the semiconductor substrate 200 of FIG. 2) during various phases of a deposition process, such as a chemical vapor deposition process, within a chamber 403 of the reactor apparatus 402. For example, the semiconductor wafer 504 is a handle substrate 102/302 (FIGS. 1 and 3) upon which a charge trapping layer 106 is deposited using chemical vapor deposition. The wafer 504 is supported in the reactor apparatus 402 by a susceptor 501. The susceptor 501 is mounted on arms 503, which, in turn, are mounted to a susceptor support shaft 505. The susceptor support shaft 505 is slidingly mounted within a bore 506 of a wafer lift shaft 507. An actuator (not shown), such as an electric or pneumatic motor, is operable to raise and lower the susceptor support shaft 505 and the wafer lift shaft 507 to various positions. The actuator may also rotate the susceptor 501. Rigid pins 509 are slidingly mounted to susceptor 501 and, when not elevated by the susceptor 501, are supported by stops 511 of the wafer lift shaft 507. The rigid pins 509 may support the wafer 504 when brought into contact with the wafer.

During an exchange or wafer loading phase, a blade 513 carries the wafer 504 into position above the pins 509. Subsequently, the wafer lift shaft 507 elevates, causing the pins 509 to translate upwards and support the wafer 504. The blade 513 includes a notch 514 to allow room for one of the pins 509 that would otherwise collide with the blade 513. Once the wafer 504 is supported by the pins 509, the blade 513 is withdrawn from the reactor apparatus 402. Next, the susceptor support shaft 505 elevates, causing the susceptor 501 to move upwards and come into contact with the wafer 504. Thereafter, the wafer 504 is supported by the susceptor 501. The susceptor support shaft 505 continues to elevate until the susceptor 501 and the wafer 504 are level with a preheat ring 515 of the reactor apparatus 402. At this point, the wafer 504 and the susceptor 501 are suitably positioned for a process step performed in the reactor apparatus 402.

FIG. 6 is a plan view of the reactor apparatus 402, including certain components that are not shown in FIG. 5. The wafer 504 is supported on the susceptor 501 in the chamber 403 of the reactor apparatus 402. During a deposition process performed using the reactor apparatus 402, process gases 536 are introduced into the reactor apparatus 402 as described above. The reactor apparatus 402 includes the chamber 403 defining a center zone 518, a front zone 520, and a side zone 522. Although not shown, the reactor apparatus 402 may also have a rear zone (opposite the front zone 520), and a second side zone (opposite the side zone 522). In the center zone 518, the reactor apparatus 402 includes a center heating device 526, such as a heat lamp, and a center temperature sensor 524, such as a thermocouple or a pyrometer, that measures the temperature of the center zone 518. In the front zone 520, the reactor apparatus 402 includes a front heating device 530, for example a heat lamp, and a front temperature sensor 528, such as a thermocouple or a pyrometer, that measures the temperature of the front zone 520. In the side zone 522, the reactor apparatus 402 includes a side heating device 534, such as a heat lamp, and a side temperature sensor 532, such as a thermocouple or a pyrometer, that measures the temperature of the side zone 522. The rear zone (not shown) and the second side zone (not shown) may also be equipped with a heating device and temperature sensor, similar to the other zones 518-522 of the reactor apparatus.

The controller 404 is communicatively coupled to the heating devices 526, 530, 534 and the temperature sensors 524, 528, 532. The controller 404 executes feedback control (e.g., proportional-integral-derivative, PID, control) to transmit instructions 406 to the heating devices 526, 530, 534 based on feedback 408 received from the temperature sensors 524, 528, 532. In particular, the controller 404 controls the power output of the heating device 526, 530, 534 in each zone 518-522 according to a target temperature set point and based on the feedback 408 of the measurement temperature in the zone 518-522 from the temperature sensors 524, 528, 532. The controller 404 may include one or multiple PID controllers for controlling the heating devices 526, 530, 534 based on the respective measured temperature in each zone 518-522. The PID controller(s) may be integrated in a single computing device (e.g., the computing device 700 of FIG. 7), or may each include a separate computing device (e.g., separate computing devices 700).

During a process step, the susceptor 501 rotates as the heating devices 526, 530, 534 FIG. 6, such as heat lamps, of the reactor apparatus 402 heat the wafer 504. The process gases 536 FIG. 6, which can include cleaning, etching, annealing, and/or deposition precursor gases are introduced into the reactor apparatus 402 during the process step at suitable temperatures and pressures, at suitable times, and for a suitable duration. Process steps that may be performed in the reactor apparatus include pretreatment processes, for example, a pretreatment step during which an oxide layer (e.g., a silicon oxide layer) is removed from the surface(s) of the wafer 504, and deposition processes, for example, a deposition step during which a charge trapping layer 106 or an epitaxial single crystal semiconductor layer is deposited on the surface(s) of the wafer 504. The process steps performed on the wafer 504 to deposit a layer of material thereon (e.g., a pretreatment step, a deposition step, and an anneal step) may collectively be referred to as a “deposition process.”

Process parameters, such as the temperature of the reactor apparatus 402, the flow rates and composition of the process gases 536, and the rotation speed of the susceptor 501, typically change at various times throughout the deposition process. The discrete process parameters throughout the deposition process, as well as loading and unloading of the wafer 504 in the reactor apparatus, are controlled by the controller 404 according to a predetermined “recipe” that is developed to produce the wafer 504 having the desired characteristics when processing is complete. Desired characteristics that control process parameters include crystallographic slip in the processed wafer 504, resistivity, deposited layer thickness (e.g., thickness of the charge trapping layer 106), deposited layer thickness uniformity, quality parameters of the deposited layer (e.g., resistivity of the charge trapping layer 106), semiconductor material grain size of the charge trapping layer 106, surface roughness, wafer flatness post-deposition (e.g., site flatness or SFQR), bow and warp, and other characteristics. Using feedback (e.g., PID) control of the heating devices 526, 530, 534 based on temperature measured by the temperature sensors 524, 528, 532, the controller 404 facilitates maintaining steady state temperature conditions at a given temperature set point during a single process step as well as transitioning to higher or lower temperatures between different process steps, as dictated by the recipe.

Examples of process steps that are performed on the wafer 504 using the reactor apparatus 402 as part of a deposition process to form the charge trapping layer 106 are described below. Each process step is suitably performed in a single reactor apparatus 402. The process steps, as described below, can be performed at various conditions (e.g., temperature and duration) that can be implemented in any combination with the various conditions (e.g., temperature and duration) of each other process step. Examples of deposition processes to form the charge trapping layer are also described in U.S. Pat. No. 10,283,402, issued May 7, 2019, and U.S. Publication No. 2024/0258155, published Aug. 1, 2024, the disclosures of which are incorporated by reference in their entirety. These examples are not limiting, however, and other processes can suitably be performed on the wafer 504 within the scope of the present disclosure. For example, the systems and methods of the present disclosure can be implemented for a reactor apparatus used to deposit any suitable layer of material on the semiconductor wafer 504 to achieve desired properties or characteristics of the processed wafer.

The deposition process includes a pretreatment process step during which a surface layer of the wafer 504 is etched, either preferentially or entirely. In the example deposition process used to form the charge trapping layer 106, the surface layer includes an oxide layer (e.g., silicon oxide layer) which is etched (preferentially or entirely) from a surface of the wafer 504 during the pretreatment process step. The oxide layer may be etched during the pretreatment step to allow subsequent nucleation of the semiconductor material used to form the charge trapping layer 106 on the surface of the wafer 504. Additionally, the pretreatment step may engineer the surface of the wafer 504 for controlling grain size and film stress of the charge trapping layer 106 subsequently deposited. The oxide layer may have been previously grown on the wafer 504 (e.g., by thermal oxidation or CVD oxide deposition) or the oxide layer may be a native oxide layer on the surface of the wafer.

During the pretreatment process step, the reactor apparatus 402 is brought to a suitable pretreatment process temperature, also referred to as an etch temperature. In an example pretreatment process step, the etch temperature is between 800° C. to 1100° C., between 800° C. to 1000° C., between 800° C. to 900° C., or between 800° C. to 850° C. During the pretreatment process step, the process gases 536 introduced into the reactor apparatus 402 include pretreatment process gases that create a suitable atmosphere for etching the wafer 504. Suitable pretreatment process gases 536 for the pretreatment process step include hydrogen (H₂), hydrogen chloride (HCl), chlorine (Cl₂), or any combination of hydrogen, hydrogen chloride, and chlorine. In some pretreatment process steps, the process gases 536 include a combination of hydrogen and hydrogen chloride or a combination of hydrogen and chlorine. The pressure of the reactor apparatus 402 during the pretreatment process step may be atmospheric pressure or at a reduced temperature. For example, the pressure of the reactor apparatus 402 during the pretreatment process step may be between 1 Torr to 760 Torr. The pretreatment process step is performed for a suitable duration at the desired etch temperature and atmosphere to achieve the desired etching. For example, at the desired etch temperature, the wafer 504 is exposed to the pretreatment process gases 536 for a duration between 1 second to 300 seconds, such as between 5 seconds to 120 seconds, between 30 seconds to 90 seconds, between 45 seconds to 75 seconds, or between 10 seconds to 60 seconds.

The parameters of the pretreatment process step, including the etch temperature and duration, are controlled to achieve desired properties of the surface of the wafer 504 for subsequent deposition of the charge trapping layer 106 thereon. For example, the parameters of the pretreatment process step are controlled to entirely etch the oxide layer from the surface of the wafer 504 or preferentially etch the oxide layer to a desired thickness and texture for facilitating growth of the charge trapping layer 106. In some examples, the target thickness of the oxide layer is between 0 nanometers (entirely etched) to 25 nanometers, such as between about 0 nanometers to 5 nanometers. In examples where the oxide layer is preferentially etched, the target thickness of the oxide layer may be between 0.1 nanometers to 25 nanometers, such as between 0.5 nanometers to 5 nanometers. In these examples, the parameters of the pretreatment process step are also controlled to achieve uniformity in the thickness of the preferentially etched oxide layer. Additionally, in examples where the oxide layer is preferentially etched, the oxide layer may be textured with holes that facilitate controlling film stress and grain size of the charge trapping layer 106. For example, the parameters of the pretreatment process step may be controlled to texture the preferentially etched oxide layer with holes having a target size of between 5 nanometers to 1000 nanometers, such as between 5 nanometers to 500 nanometers, or between 5 nanometers to 200 nanometers, which enables the engineering of the grain size as well as the film stress in the charge trapping layer 106.

The deposition process includes a seed deposition process step that is performed after the pretreatment process step, and prior to depositing the remainder of semiconductor material used to produce the charge trapping layer 106. The seed deposition process step is performed to deposit a semiconductor seed layer on the surface of the wafer 504. The semiconductor seed layer is used to promote growth of subsequently deposited semiconductor material in producing the charge trapping layer 106 and improve charge trapping efficiency of the charge trapping layer 106. The charge trapping layer 106 may thus include the semiconductor seed layer and the subsequently deposited semiconductor material. As discussed above, the charge trapping layer 106 includes polycrystalline or amorphous silicon, silicon germanium, silicon carbide, carbon-doped silicon, germanium, and combinations thereof. Suitable materials for the semiconductor seed layer also include polycrystalline or amorphous silicon, silicon germanium, silicon carbide, carbon-doped silicon, germanium, and combinations thereof. The semiconductor seed layer may be the same material as the subsequently deposited semiconductor material of the charge trapping layer 106 or may be a different semiconductor material.

During the seed deposition process step, the reactor apparatus 402 is brought to a suitable seed deposition temperature. The seed deposition temperature is greater than the etch temperature in the example deposition process. In an example seed deposition process step, the seed deposition temperature is greater than 850° C., such as between 850° C. to 1100° C., or between 850° C. to 1000° C. During the seed deposition process step, the process gases 536 introduced into the reactor apparatus 402 include suitable precursor gases for depositing the semiconductor seed layer. For example, the precursor gases are suitable for depositing the semiconductor seed layer by CVD. The composition of the precursor gases for depositing the semiconductor seed layer vary depending on the desired material of the semiconductor seed layer. For a semiconductor seed layer that includes silicon, suitable precursor gases include, for example, methyl silane, silicon tetrahydride (silane), trisilane, disilane, pentasilane, neopentasilane, tetrasilane, dichlorosilane (SiH₂Cl₂), trichlorosilane (SiHCl₃), silicon tetrachloride (SiCl₄), and combinations thereof, and in particular embodiments, the silicon precursor gas for the semiconductor seed layer includes silane, dichlorosilane, trichlorosilane, and combinations thereof. The pressure of the reactor apparatus 402 during the seed deposition process step may be atmospheric pressure or at a reduced temperature. For example, the pressure of the reactor apparatus 402 during the seed deposition step may be between 1 Torr to 760 Torr. The seed deposition process step is performed for a suitable duration at the seed deposition temperature to grow the semiconductor seed layer to the desired thickness. For example, at the desired seed deposition temperature, the wafer 504 is exposed to the precursor gases for a duration between 1 second to 60 seconds, such as between 1 second to 30 seconds, or between 1 second to 10 seconds.

The parameters of the seed deposition process step, including the seed deposition temperature and duration, are controlled to achieve a target thickness and thickness uniformity of the semiconductor seed layer. The target thickness of the semiconductor seed layer is less than the target thickness of the charge trapping layer 106. For example, the target thickness of the semiconductor seed layer is less than 20 micrometers, less than 10 micrometers, or less than 1 micrometer, such as between 10 nanometers to 20 micrometers, between 10 nanometers to 1 micrometers, between 10 nanometers to 500 nanometers, between 50 nanometers to 500 nanometers, or between 50 nanometers to 200 nanometers.

The deposition process for the charge trapping layer 106 also includes a seed anneal process step that is performed after the seed deposition process step, and prior to depositing the remainder of semiconductor material used to produce the charge trapping layer 106. The seed deposition process step is concluded by ceasing flow of the precursor gases into the reactor apparatus 402 in order to perform the seed anneal process step. The seed anneal process step is performed to anneal the semiconductor seed layer, which contributes to desirable charge trapping layer properties, such as obtaining a clean surface, a high purity film, a high resistivity film, desired nuclei size and uniformity, and reduction of residual film stress.

During the seed anneal process step, the reactor apparatus 402 is brought to a suitable seed anneal temperature. The seed anneal temperature is greater than the seed deposition temperature in the example deposition process. Annealing the semiconductor seed layer at elevated temperatures contributes to reducing film stress. In an example seed anneal process step, the seed anneal temperature is greater than 1000° C., such as between 1000° C. to 1200° C., or between 1000° C. to 1100° C. During the seed anneal process step, flow of the precursor gases is stopped and the process gases 536 introduced into the reactor apparatus 402 include anneal process gases that create a suitable atmosphere for annealing the semiconductor seed layer. Suitable anneal process gases 536 for the seed anneal process step include hydrogen (H₂), hydrogen chloride (HCl), chlorine (Cl₂), or any combination of hydrogen, hydrogen chloride, and chlorine. The pressure of the reactor apparatus 402 during the seed anneal process step may be atmospheric pressure or at a reduced temperature. For example, the pressure of the reactor apparatus 402 during the seed anneal process step may be between 1 Torr to 760 Torr. The seed anneal process step is performed for a suitable duration at the desired seed anneal temperature and atmosphere to anneal to semiconductor seed layer. For example, at the desired seed anneal temperature, the semiconductor seed layer is annealed for a duration between 1 second to 300 seconds, such as between 5 seconds to 60 seconds, between 10 seconds to 60 seconds, between 10 seconds to 45 seconds, or between 10 seconds to 40 seconds.

The parameters of the seed anneal process step, including the seed anneal temperature and duration, are controlled to achieve desired properties of the semiconductor seed layer for subsequent deposition of the remaining semiconductor material of the charge trapping layer 106 thereon. For example, the parameters of the seed anneal process step are controlled to achieve desired nuclei size and uniformity, and reduction of residual film stress in the semiconductor seed layer. In some examples, the parameters of the seed anneal process step are controlled in order to reduce film stress in the semiconductor seed layer to a range between 0 MPa to 500 MPa, such as between 0 MPa to 100 MPa.

After the seed anneal process step, deposition of the charge trapping layer 106 resumes with a charge trapping layer (CTL) deposition process step. During the CTL deposition process step, the reactor apparatus 402 is brought to a suitable CTL deposition temperature. The CTL deposition temperature is lower than the seed anneal temperature in the example deposition process, and an intermediate cooling step may be included between the seed anneal process step and the CTL deposition process step to reduce a temperature of the reactor apparatus 402. The CTL deposition temperature may be approximately equal to the seed deposition temperature, or the CTL deposition temperature may be different from (e.g., higher than) the seed deposition temperature. In an example CTL deposition process step, the CTL deposition temperature is greater than 850° C., such as between 850° C. to 1100° C., or between 850° C. to 1000° C. During the CTL deposition process step, the process gases 536 introduced into the reactor apparatus 402 include suitable precursor gases for depositing the charge trapping layer 106. For example, the precursor gases are suitable for depositing the charge trapping layer 106 by CVD. The precursor gases for the CTL deposition process step may be the same precursor gases used during the seed deposition process step. The composition of the precursor gases for depositing the charge trapping layer 106 vary depending on the desired material of the charge trapping layer 106. For a charge trapping layer 106 that includes silicon, suitable precursor gases include, for example, methyl silane, silicon tetrahydride (silane), trisilane, disilane, pentasilane, neopentasilane, tetrasilane, dichlorosilane (SiH₂Cl₂), trichlorosilane (SiHCl₃), silicon tetrachloride (SiCl₄), and combinations thereof, and in particular embodiments, the silicon precursor gas for the charge trapping layer includes silane, dichlorosilane, trichlorosilane, and combinations thereof. The pressure of the reactor apparatus 402 during the CTL deposition process step may be atmospheric pressure or at a reduced temperature. For example, the pressure of the reactor apparatus 402 during the CTL deposition step may be between 1 Torr to 760 Torr. The CTL deposition process step is performed for a suitable duration at the CTL deposition temperature to grow the charge trapping layer 106 to the desired thickness. For example, during the CTL deposition process step, the wafer 504 is exposed to the precursor gases at the desired CTL deposition temperature for a duration between 100 seconds to 300 seconds, such as between 100 seconds to 200 seconds, or between 125 seconds to 175 seconds.

The CTL deposition process step may continue at the CTL deposition temperature until the charge trapping layer 106 has a thickness of at least 0.1 micrometer, at least 1 micrometer, or at least 2 micrometers, such as between 0.1 micrometer and 50 micrometers, between 0.1 micrometer and 20 micrometers, between 0.1 micrometer and 10 micrometers, between 0.5 micrometer and 5 micrometers, between 0.5 micrometer and 3 micrometers, between 1 micrometer and 10 micrometers, between 1 micrometer and 5 micrometers, or between 2 micrometers and 5 micrometers. In some embodiments, the charge trapping layer 106 has a target resistivity of at least 500 Ohm-cm, at least 1000 Ohm-cm, or at least 3000 Ohm-cm, such as between 500 Ohm-cm to 100,000 Ohm-cm, between 1000 Ohm-cm to 10,000 Ohm-cm, between 2000 Ohm-cm to 10,000 Ohm-cm, between 3000 Ohm-cm to 10,000 Ohm-cm, or between 3000 Ohm cm to 5000 Ohm-cm.

The deposition process for the charge trapping layer 106 also includes a CTL anneal process step that is performed after, or in conjunction with, the CTL deposition process step. In some examples, the CTL deposition and anneal process steps are performed as a series of deposition and anneal cycles to produce the charge trapping layer 106, as described in U.S. Publication No. 2024/0258155, which is incorporated by reference. The CTL deposition process step is concluded or temporarily interrupted for the CTL anneal process step by ceasing flow of the precursor gases into the reactor apparatus 402. The CTL anneal process step is performed to anneal the charge trapping layer 106, which contributes to desirable charge trapping layer properties, such as grain size and film stress in the charge trapping layer 106. During the CTL anneal process step, the reactor apparatus 402 is brought to or maintained at a CTL anneal temperature. The CTL anneal temperature may be approximately the same temperature as the CTL deposition temperature, e.g., greater than 850° C., such as between 850° C. to 1100° C., or between 850° C. to 1000° C. In these examples, the CTL anneal temperature may be less than the seed anneal temperature. Alternatively, the CTL anneal temperature may be higher than the CTL deposition temperature, e.g., greater than 1000° C., such as between 1000° C. to 1200° C., or between 1000° C. to 1100° C. In these examples, the CTL temperature may be approximately the same temperature as the seed anneal temperature. During the CTL anneal process step, flow of the precursor gases is stopped and the process gases 536 introduced into the reactor apparatus 402 include anneal process gases that create a suitable atmosphere for annealing the semiconductor seed layer. Suitable anneal process gases 536 for the CTL anneal process step include hydrogen (H₂), hydrogen chloride (HCl), chlorine (Cl₂), or any combination of hydrogen, hydrogen chloride, and chlorine. The CTL anneal process gases may be the same as the anneal process gases used during the seed anneal process step. The pressure of the reactor apparatus 402 during the CTL anneal process step may be atmospheric pressure or at a reduced temperature. For example, the pressure of the reactor apparatus 402 during the seed anneal process step may be between 1 Torr to 760 Torr. The CTL anneal process step is performed for a suitable duration at the desired CTL anneal temperature and atmosphere to anneal to charge trapping layer 106. For example, during the CTL anneal process step, the wafer 504 is exposed to the anneal gases at the desired CTL anneal temperature for a duration between 100 seconds to 300 seconds, such as between 100 seconds to 200 seconds, or between 125 seconds to 175 seconds. Where the CTL deposition and anneal process steps are performed cyclically, the duration of each process step is the total duration from all cycles performed. Where a single CTL anneal process step is performed, after depositing the entire charge trapping layer 106, the CTL anneal duration may be relatively shorter, such as between 1 second to 300 seconds, between 5 seconds to 60 seconds, or between 10 seconds to 40 seconds. After the CTL deposition and anneal steps, the charge trapping layer 104 may have a film stress controlled to within a range between 0 MPa to 500 MPa, such as between 0 MPa to 100 MPa.

### Systems and Methods for Consistently Controlling Process Parameters During the Deposition Process Across Multiple Reactor Apparatus

Throughout the deposition process, in order to achieve the desired properties following each process step, the process parameters must be well-controlled. As described above, the controller 404 operates to control the reactor apparatus 402 according to the predetermined recipe that is developed to produce the wafer 504 having the desired characteristics when processing is complete including, for example, crystallographic slip in the processed wafer 504, resistivity of the wafer 504 and the charge trapping layer 106, deposited layer thickness, deposited layer thickness uniformity, grain size of the charge trapping layer 106, surface roughness, wafer flatness post-deposition (e.g., site flatness or SFQR), bow and warp, and other characteristics. A key aspect of the control process implemented by the controller 404 is the reliability of the data 408 transmitted by the reactor apparatus 402 regarding the deposition process, for example, the accuracy of temperature measurements obtained using temperature sensors 524, 528, 532 in the reactor apparatus 402. Inaccurate measurements (e.g., temperature measurements) could result in the controller 404 delivering too much or too little power to the heating devices 526, 530, 534 in the reactor apparatus 402, which in turn causes the temperature in the reactor apparatus 402 to rise above or fall below the target temperature set point for the process step and risks producing the charge trapping layer 106 with undesired properties. The controller 404 compensates for any inaccurate measurements by applying offsets to the measurements (e.g., by applying a temperature offset to each temperature measured by the temperature sensors 524, 528, 532). Since the accuracy of the temperature measurement varies between the temperature sensors 524, 528, 532, different temperature offsets are applied for the different temperature sensors 524, 528, 532. Initially, the temperature offsets may be empirically determined and/or specified by the manufacturer for a specific model and configuration of the reactor apparatus 402. According to the present disclosure, the temperature offsets are adjusted from any initial settings and stored as predetermined temperature offsets in the memory 710 of the controller 404 to both compensate for inaccurate measurements from the sensors of the different zones 518-522 of the reactor apparatus 402 and to control one or more characteristics of the semiconductor wafer following the each process step. In embodiments, multiple sets of temperature offsets are stored in the memory 710, each corresponding to one or more process steps and predetermined to control a characteristic of the processed wafer following the respective one or more process steps. The temperature offsets may be stored in the memory 710 of the controller 404 and applied when executing feedback control of the heating devices 526, 530, 534 in the reactor apparatus 402 using the temperature sensors 524, 528, 532.

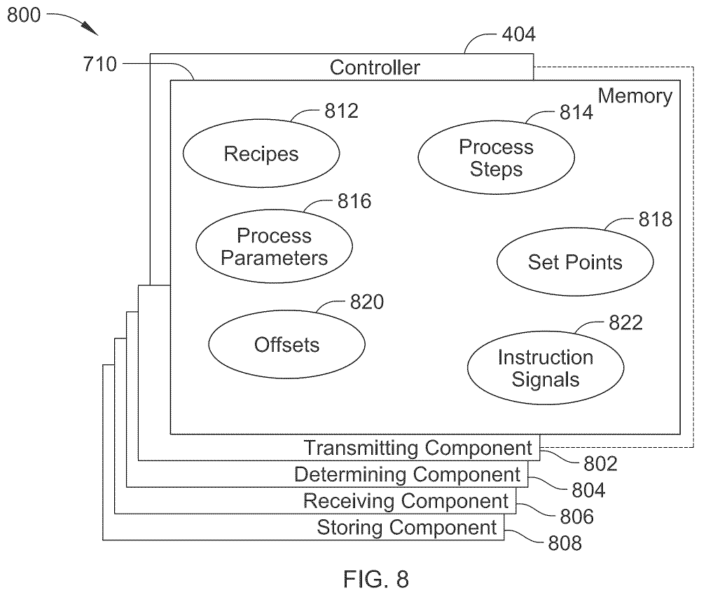

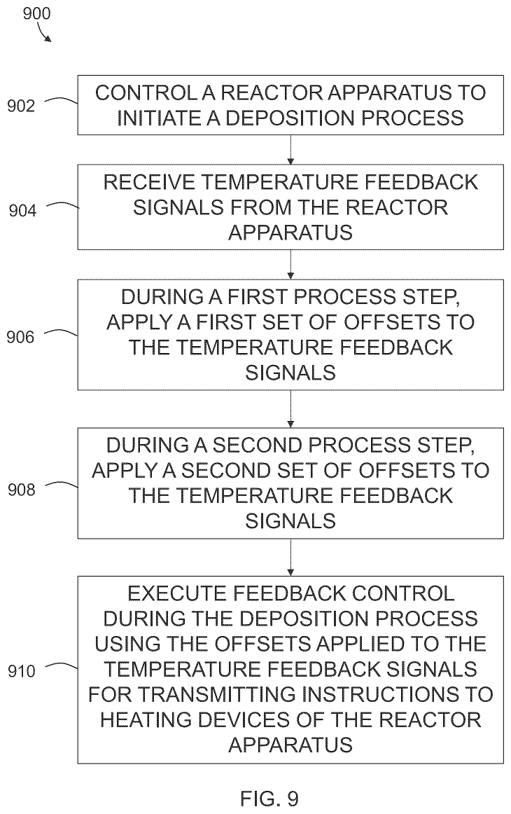

Referring to FIG. 8, a diagram 800 of components of the controller 404 and a configuration of data in the memory 710 is shown. The components enable to controller 404 to control a deposition process with the reactor apparatus 402. An example process flow 900 for controlling a deposition process is shown in FIG. 9 and described below. The controller 404 includes a transmitting component 802 for transmitting instructions 406 to components of the reactor apparatus 402 for controlling parameters (e.g., temperatures, duration, process gas flow rate and composition, susceptor rotation) in the reactor apparatus 402. For example, the transmitting component 802 transmits power instructions to the heating devices 526, 530, 534 of the reactor apparatus 402 to control an output power at which the respective heating device 526, 530, 534 operates to achieve a target temperature in the respective zone 518-522. The controller 404 also includes a determining component 804 for determining the target process parameter set points (e.g., temperature set points) for each of the zones 518-522 of the reactor apparatus 402 and a receiving component 806 for receiving process parameter feedback signals 408 (e.g., temperature measurement feedback) from sensors (e.g., temperature sensors 524, 528, 532) in each zone 518-522. The controller 404 determines the target process parameter (e.g., temperature) set points using the determining component 804 and the feedback signals 408 received by the receiving component 806 according to a predetermined recipe of the deposition process and offsets (e.g., temperature offsets) for the sensors (e.g., temperature sensors 524, 528, 532) of the reactor apparatus 402. Deposition process recipes, process parameter set points, and offsets are saved in the memory 710 of the controller 404, which additionally includes a storing component 808 for storing information related to deposition processes (e.g., recipes, feedback, process parameter set points, offsets) associated with the reactor apparatus 402 in the memory 710.

In some embodiments, data stored in the memory 710 is divided into a plurality of sections, including but not limited to, a recipes section 812, a process steps section 814, a process parameters section 816, a process parameter set points section 818, an offsets section 820, and an instruction signals section 822. These sections within the memory 710 are interconnected to retrieve and store information in accordance with the functions and processes described below.

FIG. 9 is an example process flow 900 in which the controller 404 controls operation of the reactor apparatus during a deposition process, such as the deposition process to form the charge trapping layer 106 described above. The process flow 900 is executed by the controller 404 using the components of the controller 404 described herein, for example, with respect to FIG. 7 and the computing device 700. For example, the controller 404 is configured to execute the process flow 900 via the processor 705 which executes instructions stored in the memory 710 of the controller 404, and, optionally, via one or more ancillary components of the computing device 700.

In the example process flow 900, the controller 404 controls the reactor apparatus 402 to perform a deposition process on a semiconductor wafer (e.g., the wafer 504 and/or the substrate 200) that includes a first process step and a second process step. The deposition process is not limited to only including a first and second process steps. Any number of process steps may be included in the deposition process, such as two, three, four, five, or more than five process steps. The number of process steps will depend on the particular deposition process being performed by the reactor apparatus 402.

In some examples, the controller 404 executes the process flow 900 to control the reactor apparatus 402 to perform the deposition process by which the charge trapping layer 106 is formed on the semiconductor wafer, as described above. This deposition process includes, as a first process step, the pretreatment process step and, as a second process step, a deposition process step. The second process step may include the seed deposition process step and/or the CTL process step. In some examples, the second process step includes the seed deposition process step, the seed anneal process step, the CTL deposition process step, and/or the CTL anneal process step. The second process step may include one, some, or all the seed deposition process step, the seed anneal process step, the CTL deposition process step, and the CTL anneal process step. In some examples, the seed anneal process step and/or the CTL anneal process step may be described as a third process step. In some examples, the deposition process includes: as a first process step, the pretreatment process step; as a second process step, the seed deposition process step and/or the CTL deposition process step; and, as a third process step, the seed anneal process step and/or the CTL anneal process step.

In accordance with the process flow 900, the controller 404 controls 902 the reactor apparatus to initiate the deposition process. The controller 404 may control 902 the reactor apparatus according to a recipe stored in the memory 710. The recipe designates the process steps of the deposition process and the process parameters (e.g., temperatures, duration, process gas flow rate and composition, susceptor rotation) for each process step. Controlling 902 the reactor apparatus 402 also includes transmitting instructions 406 to components of the reactor apparatus 402 to control the process parameters during each process step. For example, the controller 404 controls 902 the reactor apparats including by transmitting instructions to the heating devices 526, 530, 534 of the reactor apparatus 402 to control an output power at which the respective heating device 526, 530, 534 operates to achieve a target temperature in the respective zone 518-522 for the respective process step.

During each process step, the controller 404 also receives 904 feedback signals 408 from sensors (e.g., the temperature sensors 524, 528, 532) of each zone 518-522 of the reactor apparatus 402, which are used by the controller 404 to execute feedback control (e.g., PID control) for adjusting (e.g., continuously, periodically, or intermittently) the instructions 406 being transmitted to the components of the reactor apparatus 402. For example, the controller 404 executes feedback control (e.g., PID control) to adjust (e.g., continuously, periodically, or intermittently) the instructions 406 being transmitted to the heating devices 526, 530, 534 based on feedback 408 received 904 from the temperature sensors 524, 528, 532.

In accordance with the present disclosure, the controller applies offsets, which are stored in the memory 710, to the feedback signals received 904 from the sensors (e.g., to the temperature feedback signals received from the temperature sensors 524, 528, 532) and executes the feedback control using the feedback signals with the offsets applied thereto. As described in more detail below, the applied offsets are predetermined to control one or more characteristics of the semiconductor wafer following each process step. In particular, during the first process step, the controller 404 applies 906 a first set of offsets to the temperature feedback signals received 904 from the temperature sensors 524, 528, 532. During the second process step, the controller 404 applies 908 a second set of offsets to the temperature feedback signals received 904 from the temperature sensors 524, 528, 532.

The controller 404 executes 910 feedback control throughout the deposition process using the feedback signals with different sets of offsets being applied 906, 908 at the different process steps, to determine instructions for components of the reactor apparatus 402 (e.g., the heating devices 526, 530, 534) during each process step and transmits the instructions to the components of the reactor apparatus 402 accordingly. For example, the controller 404 executes 910 the feedback control to control the power output of the heating devices 526, 530, 534 according to a target temperature of each process step using the temperature feedback signals and the set of offsets applied 906, 908 for the particular process step. The target temperature of each process step may vary, and may be set according to the predetermined recipe of the deposition process.

Each of the first set of offsets and the second set of offsets includes an offset for each temperature feedback signal, for example, for each one of the three temperature feedback signals received from the three temperature sensors 524, 528, 532. The offsets included in the sets of offsets for the respective feedback signals may be the same or different from each other. Differences between the offsets of each set represents a different compensation factor needed for each sensor (e.g., each temperature sensor 524, 528, 532) of the different zones 518-522 of the reactor apparatus 402.

In accordance with the present disclosure, each of the first set of offsets and the second set of offsets is predetermined to both compensate for inaccurate measurements from the sensors of the different zones 518-522 of the reactor apparatus 402 and to control one or more characteristics of the semiconductor wafer following the respective process step. In particular, the first set of offsets is predetermined to control a first characteristic of the semiconductor wafer following the first process step. The second set of offsets is predetermined to control a second characteristic of the semiconductor wafer following the second process step. The first and second characteristics may be different characteristics, which enables controlling the offsets to characteristics that are particularly and/or discretely affected by the process parameters of the respective process step. For example, the first characteristic controlled by the first set of offsets may be thickness uniformity of an etched surface (e.g., oxide) layer of the semiconductor wafer following the pretreatment process step. The second characteristic controlled by the second set of offsets may be crystallographic slip of the wafer following the deposition process step (and, optionally, the anneal process step). The crystallographic slip is a characteristic of the wafer that is particularly and/or discretely affected at the elevated temperature conditions during the deposition and anneal process steps, whereas the surface (e.g., oxide) layer thickness uniformity must be controlled during the first process step to prevent against unacceptable properties of the subsequently deposited layer (e.g., the charge trapping layer 106), such as unacceptable bow, warp, flatness, thickness, grain size, resistivity, and/or film stress. In this way, the controller 404 applies different sets of offsets (e.g., temperature offsets) to the feedback signals (e.g., the temperature feedback signals) during different process steps to facilitate a well-controlled deposition process that can achieve a deposited layer with the desired properties.

The different sets of offsets that are stored in the memory 710 of the controller 404 can be predetermined based on control or test runs of the reactor apparatus 402 to ensure that the deposition process is repeatedly and consistently performed in the reactor apparatus 402. The control or test runs used to determine the different sets of offsets applied during the different process steps of the deposition process can be performed when the reactor apparatus 402 is newly configured for performing the deposition process or when the reactor apparatus 402 is returned from maintenance. As described above, the controller 404 stores a predetermined recipe that is developed to produce the semiconductor wafer having the desired characteristics when the deposition process is complete. The predetermined recipe is standardized such that the same recipe is stored and executed by controllers 404 used in conjunction with different reactor apparatus 402. Even in instances where the same model or type of reactor apparatus 402 is used, some differences may exist that require applying different offsets between the reactor apparatus 402. Moreover, even if each reactor apparatus 402 is configured with its own offsets for sensor (e.g., temperature sensor) feedback signals, these are typically based on standard empirical data or specifications by the manufacturer, and are not fine-tuned for a particular deposition process performed using the reactor apparatus 402 and, more particularly, for the different process steps of a deposition process performed using the reactor apparatus 402 that may affect different characteristics of the wafer during the deposition process. Accordingly, storing predetermined sets of offsets in the memory 710 of the controller 404, which are particularly tuned for the reactor apparatus 402, for use in conjunction with different process steps of the predetermined recipes enables each reactor apparatus 402 used for the deposition process to produce the semiconductor wafer with the desired characteristics in a reliable, consistent, and efficient manner.

In some examples, the target temperatures stored in the memory 710 and used by the controller 404 to execute 910 the feedback control are determined according to target temperature setpoints of the recipe for the different process steps, which target temperature setpoints are adjusted to the target temperatures to control a characteristic of the semiconductor wafer following the deposition process. For example, the target temperature for each process step may include an adjustment made to the target temperature setpoint of the respective process step to control a thickness of the deposited layer of material (e.g., the charge trapping layer 106) on the semiconductor wafer following the deposition process using the particular reactor apparatus 402. The adjustments made to the target temperatures are particular to the reactor apparatus 402, and may be determined according to empirical data from control or test runs using the reactor apparatus 402 to perform the entire deposition process. The control or test runs used for adjusting the target temperatures that are applied to the deposition process performed in the reactor apparatus 402 are suitably performed after the controller 404 is configured with the predetermined sets of offsets used for the different process steps for controlling the respective characteristics of the wafer following each process step. Adjusting the target temperatures in this way may ensure that the desired thickness of the deposited layer of material is achieved consistently and repeatedly across different reactor apparatus 402.

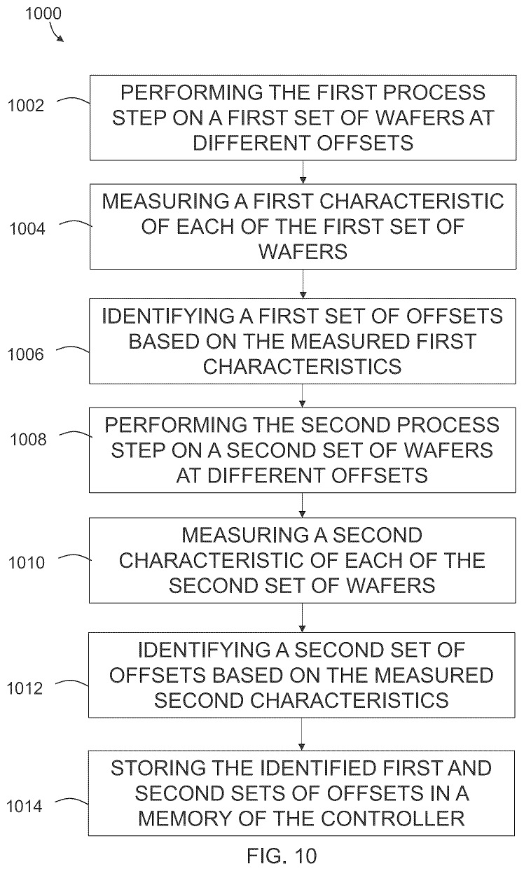

FIG. 10 is an example process flow 1000 of determining offsets (e.g., temperature offsets) and target temperatures to be applied during different process steps of a deposition process performed using a reactor apparatus 402. More broadly, the example process flow 1000 is implemented to configure a controller 404 to control operation of a reactor apparatus 402 according to the process flow 900 of FIG. 9, to ensure that the reactor apparatus 402 can consistently and repeatedly perform a deposition process according to a predetermined recipe and produce the semiconductor wafer having the desired characteristics when the deposition process is complete. In embodiments of the present disclosure, the temperature offsets are determined in accordance with the process flow 1000 of FIG. 10 and stored as predetermined temperature offsets in the memory 710 of the controller 404 for subsequent use by the controller 404 in executing the operations of the process flow 900 of FIG. 9.

The process flow 1000 includes performing 1002 the first process step of the deposition process on each of a first set of semiconductor wafers using the reactor apparatus 402, during which the controller 404 controls operation of the reactor apparatus 402 using a first set of offsets (e.g., temperature offsets) applied to the feedback signals (e.g., temperature feedback signals). For each semiconductor wafer on which the first process step is performed 1002, the first set of offsets is different than the other wafers of the first set. In some examples, a control or baseline first set of offsets is used for one of the wafers of the first set, and the first set of offsets used for the other wafers of the first set is selected by changing (increasing or decreasing) the value of the baseline first set of offsets. For simplicity, the change in value can be the same for each of the offsets of the first set of offsets.

As an illustrative example, the baseline first set of offsets may be a set of temperature offsets {Baseline Temperature Offset 1, Baseline Temperature Offset 2, Baseline Temperature Offset 3} that are empirically determined and/or specified by the manufacturer of the reactor apparatus 402 for applying to temperature feedback signals received from the temperature sensors 524, 528, 532, respectively. This baseline set of temperature offsets is applied when performing 1002 the first process step on one of the semiconductor wafers of the first set. For each other one of the semiconductor wafers of the first set, the first set of temperature offsets applied when performing 1002 the first process step is either increased or decreased by some value, such that each semiconductor wafer is subjected to the first process step using different temperature offsets. For example, for one of the semiconductor wafers, the first process step may be performed 1002 using a set of temperature offsets {Baseline Temperature Offset 1+10, Baseline Temperature Offset 2+10, Baseline Temperature Offset 3+10}, and for another one of the semiconductor wafers, the first process step may be performed 1002 using a set of temperature offsets {Baseline Temperature Offset 1-5, Baseline Temperature Offset 2-5, Baseline Temperature Offset 3-5}.

The process flow 1000 also includes measuring 1004 a first characteristic of each of the first set of semiconductor wafers after performing 1002 the first process step. The first characteristic that is measured 1004 is suitably a characteristic that is affected by the first process step and/or affects the subsequent process step(s) of the deposition process. In some examples, the first process step is the pretreatment process step of the deposition process for the charge trapping layer 106, in which the oxide layer is etched (entirely or preferentially). In these examples, the first characteristic that is measured 1004 can suitably be a thickness of the oxide layer at different points on the surface of the wafer. For example, the thickness of the oxide layer can be measured proximate a front of the wafer, proximate a center of the wafer, and proximate a side of the wafer, corresponding to the locations of the different zones 518-522 of the reactor apparatus 402 (see FIG. 6). Measuring the thickness of the oxide layer can reveal whether the first (pretreatment) process step performed 1002 on each wafer achieved the desired thickness and thickness uniformity of the oxide layer following the etching. The thickness of the oxide layer can be measured 1004 using any suitable inspection tool, such as an ellipsometer.

The measured 1004 first characteristics are used to identify 1006 a first set of offsets that will be used by the controller 404 to control the reactor apparatus 402 during the deposition process. Suitably, the identified 1006 first set of offsets corresponds to the set of offsets implemented at step 1002 and that produced the semiconductor wafer of the first set having the most optimal measured 1004 first characteristic. For example, the identified 1006 first set of offsets suitably correspond to the set of offsets implemented at step 1002 and that produced the semiconductor wafer having the most optimal oxide layer thickness and thickness uniformity. The identified 1006 first set of offsets is then stored in the memory 710 of the controller and can be implemented by the controller 404 as a predetermined first set of offsets for operating the reactor apparatus 402 during the first process step of the deposition process.

The process flow 1000 also includes performing 1008 the second process step of the deposition process on each of a second set of semiconductor wafers using the reactor apparatus 402, during which the controller 404 controls operation of the reactor apparatus 402 using a second set of offsets (e.g., temperature offsets) applied to the feedback signals (e.g., temperature feedback signals). The second set of semiconductor wafers may be a different set of wafers than the first set. The second process step may be performed 1008 on the second set of wafers after the first process step. The first process step may be performed on the second set of wafers prior to performing 1008 the second process step using the identified 1006 first set of offsets.

Similar to the first sets of offsets used for performing 1002 the first process step on the first set of wafers, for each semiconductor wafer on which the second process step is performed 1008, the second set of offsets is different than the other wafers of the second set. In some examples, a control or baseline second set of offsets is used for one of the wafers of the second set, and the second set of offsets used for the other wafers of the second set is selected by changing (increasing or decreasing) the value of the baseline first set of offsets, similar to as described above for the first sets of offsets. For simplicity, the change in value can be the same for each of the offsets of the second set of offsets. The baseline second set of offsets may be the identified 1006 first set of offsets. Alternatively, the baseline second set of offsets may be the same set as the baseline first set of offsets described above.

The process flow 1000 also includes measuring 1010 a second characteristic of each of the second set of semiconductor wafers after performing 1008 the second process step. In some examples, measuring 1010 the second characteristic may be performed after performing 1008 the second process step (e.g., a deposition process step) and any subsequent process step of the deposition process (e.g., any subsequent anneal step). The second characteristic that is measured 1010 is suitably a characteristic that is affected by the second process step and, optionally, any subsequent process step of the deposition process. In some examples, the second process step is the seed deposition process step, the CTL deposition process step, the seed anneal process step, and/or the CTL anneal process step of the deposition process for the charge trapping layer 106, which is performed at elevated temperatures relative to the pretreatment process step. In these examples, the second characteristic that is measured 1010 can suitably be a crystallographic slip of the wafer, which can be induced by the thermal conditions of the deposition and/or anneal process steps. Measuring 1010 the crystallographic slip of the wafer can reveal whether the second (deposition/anneal) process step performed 1008 on each wafer risks inducing slip in the wafer at certain offsets. The crystallographic slip of the wafer can be measured 1010 using any suitable slip inspection tool, such as a SPx series tool available from KLA, a Hologenix slip inspection tool, or an X-ray Topography slip inspection tool.

The measured 1010 second characteristics are used to identify 1012 a second set of offsets that will be used by the controller 404 to control the reactor apparatus 402 during the deposition process. Suitably, the identified 1012 second set of offsets corresponds to the set of offsets implemented at step 1008 and that produced the semiconductor wafer of the second set having the most optimal measured 1010 second characteristic. For example, the identified 1012 second set of offsets suitably correspond to the set of offsets implemented at step 1008 and that produced the semiconductor wafer having the most optimal slip performance. The identified 1012 second set of offsets is then stored in the memory 710 of the controller and can be implemented by the controller 404 as a predetermined second set of offsets for operating the reactor apparatus 402 during the second process step of the deposition process and, optionally, any subsequent process steps. For example, the identified 1012 second characteristic can be implemented in some examples for each deposition process step and each anneal process step following the pretreatment process step.

It will be appreciated that the steps 1002-1012 can be iterated for any number of process steps of the deposition process and/or any number of characteristics of the wafer to identify optimal offsets to be applied during each process step.

In some examples, the process flow 1000 also includes performing the deposition process on a third set of wafers, which may be the same as or different from the first set of wafers and/or the second set of wafers. Performing the deposition process on the third set of wafers is performed to determine the temperature targets for the deposition process when using the reactor apparatus 402. As described above, the temperature target setpoints prescribed by the predetermined recipe can suitably be adjusted to compensate for differences in the reactor apparatus 402 that affect one or more characteristics of the semiconductor wafer following the deposition process. Suitably, performing the deposition process on the third set of wafers can apply the identified 1006 first set of offsets during the first process step (e.g., the pretreatment process step) and apply the identified 1012 second set of offsets during the second process step (e.g., a deposition and/or anneal process step).

Different sets of target temperatures during the process steps can be used for each of the third set of semiconductor wafers on which the deposition process is performed using the identified 1006, 1012 first and second sets of offsets. Similar to the sets of offsets used for performing 1002, 1008 the first and second process steps on the first and second sets of wafers, for each semiconductor wafer of the third set on which the deposition process is performed, the target temperatures used are different than the other wafers of the third set. In some examples, a control or baseline set of target temperatures is used for one of the wafers of the third set, and the set of target temperatures used for the other wafers of the third set is selected by changing (increasing or decreasing) the value of the baseline set of target temperatures, as described above. For simplicity, the change in value can be the same for each of the target temperatures. The baseline set of target temperature may be the target temperature set points prescribed by the predetermined recipe of the deposition process.

In these examples, the process flow 1000 can also include measuring 1010 a third characteristic of each of the third set of semiconductor wafers after performing the deposition process. The third characteristic that is measured is suitably a characteristic of the final, fully processed wafer that is affected by the deposition process. In some examples, the third characteristic is suitably a thickness of the deposited layer of material (e.g., a thickness of the charge trapping layer 106). The thickness of the deposited layer can be measured using any suitable inspection tool, such as a WaferSight series tool available from KLA-Tencor or by using a Fourier-transform infrared spectroscopy tool. Alternatively, the third characteristic can be any property of the deposited layer (e.g., grain size, thickness uniformity, resistivity, film stress, surface roughness) and/or a property of the wafer (e.g., flatness, bow, warp).

The measured third characteristics are used to identify target temperatures used during the deposition process, which may be adjusted from the target temperature setpoints of the recipe depending on the performance of the third set of wafers under the varying sets of target temperatures. Suitably, the identified target temperatures correspond to the set of target temperatures that produced the semiconductor wafer of the third set having the most optimal measured third characteristic. For example, the identified target temperatures suitably produced the semiconductor wafer having the most optimal thickness of the deposited layer. The identified target temperatures are then stored in the memory 710 of the controller and can be implemented for the deposition process.

With the sets of offsets and target temperatures identified and stored in the memory 710 in accordance with the process flow 1000, the controller 404 is suitably configured for controlling operation of the reactor apparatus 402 during a deposition process for producing a semiconductor wafer having the desired characteristics when processing is complete. Additional adjustment can also be made, depending on the identified offsets and target temperatures and the differences, if any, that are being made to the recipe of the deposition process based on the measured performance data of the reactor apparatus 402. For example, a duration of the deposition process (or any discrete steps) of the deposition process can be adjusted to achieve a desired deposition rate based on the identified target temperatures and the measured thickness data of the deposition layer following the deposition process.

### EXAMPLES

The following non-limiting examples further illustrate the subject matter of the present disclosure.

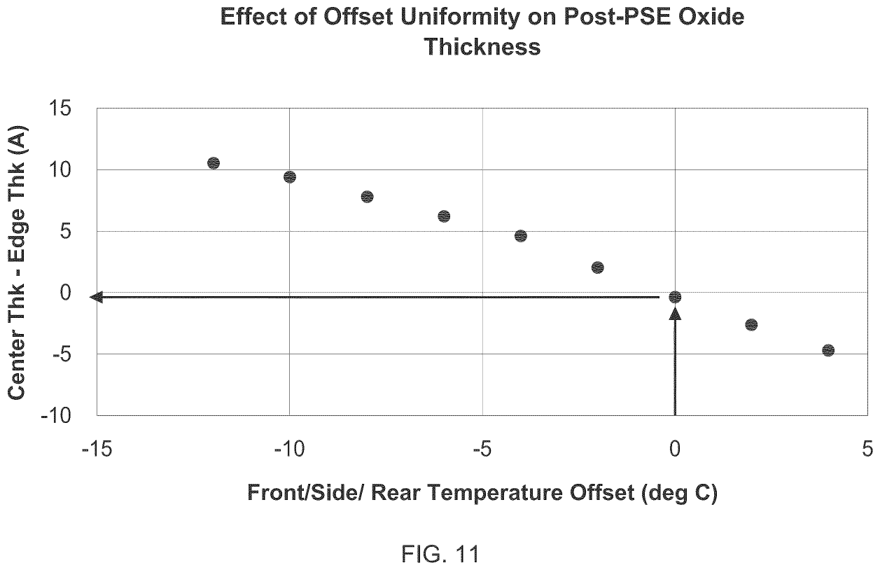

Referring to FIGS. 11-13, an example reactor apparatus was tuned in accordance with the present disclosure for performing a deposition process for a charge trapping layer 106. According to a predetermined recipe, the deposition process includes a pretreatment etch process step performed at a temperature of between 800° C. to 850° C. for about one minute, a seed deposition process step performed at between 850° C. to 950° C. for about five seconds, a seed anneal process step performed at between 1000° C. to 1100° C. for about thirty seconds, and a CTL deposition process step with in-situ annealing performed at between 900° C. to 1000° C. for about 150-160 seconds each (total deposition time and total anneal time, each). The example reactor apparatus was an ASM E3200 single chamber reactor that uses thermocouples to measure temperatures in different zones.

Referring to FIG. 11, the first step is to identify a set of offsets applied to temperature feedback signals from the thermocouples that facilitate controlling thickness uniformity in the oxide layer (e.g., uniformity in thickness of the oxide layer between the wafer center to the wafer edge) during the pretreatment etch process step. A set of test wafers were processed through the pretreatment etch process, without the subsequent deposition, with different sets of temperature offsets. The test wafers following the pretreatment etch process were unloaded to measure the native oxide thickness on an ellipsometer. In this example, the native oxide layer of the test wafers is preferentially etched to form textures (see U.S. Pat. No. 10,283,402). As such, the reported native oxide thickness values might be greater than pre-process native oxide thickness values, due to the condition of the film no longer matching what is designed into the ellipsometry model, as indicated by the poor values reported for the ‘goodness of fit.’ The optimal offset values for the pretreatment etch process are identified from the condition that gives uniform center and edge oxide thickness, as shown in FIG. 11, and these offset values are stored for the CTL deposition recipe using the reactor apparatus.

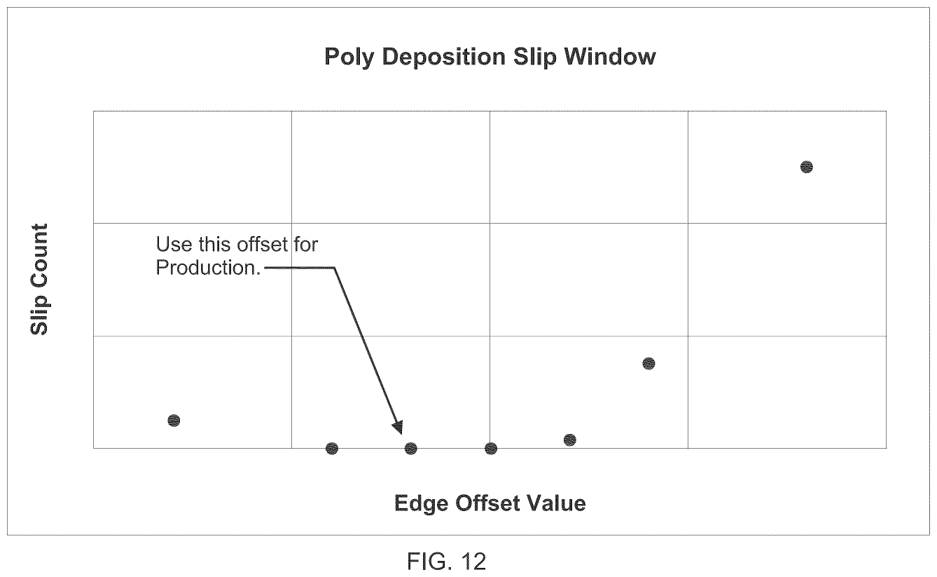

Because the pretreatment etch process step is relatively low temperature and not a risk for inducing crystallographic slip, the offsets identified from the first step, which provide good uniformity for the pretreatment etch step, are kept and used for a second step in which a standard slip window test is run for the higher temperature steps of seed deposition, seed anneal, CTL deposition, and in-situ anneal. In this second step, a slip window test is performed by running a set of test wafers through the entire CTL deposition process using the standard recipe conditions (including temperatures, times, and flows) with different temperature offsets. Following this process, the wafers are measured on a slip inspection tool such as the KLA SPx, Hologenix, or X-ray Topography (XRT). Since the surface of the deposited charge trapping layer is rough, it is necessary to inspect the backside of the wafer backside if using KLA SPx or Hologenix. A slip window test example is shown in FIG. 12. In this plot, three sets of offset conditions yield zero slip, so the center of that range of the sets of offsets is selected and will be used as the set of offsets for the higher temperature process steps (i.e., seed deposition, seed anneal, CTL deposition, and in-situ anneal). This set of offset values will likely not be the same as the offset values used in the pretreatment etch process step. The reason for choosing the center of the slip window is to minimize the possibility of generating slip on the handle wafer, which may be high resistivity and very sensitive to slip. Note that using the offset values of the center of the slip window does not guarantee the temperature of wafer center is similar as the edge during the higher temperature steps. A balance needs to be struck that optimizes between temperature uniformity, which can affect parameters like thickness uniformity, and the robustness for slip-fee performance.

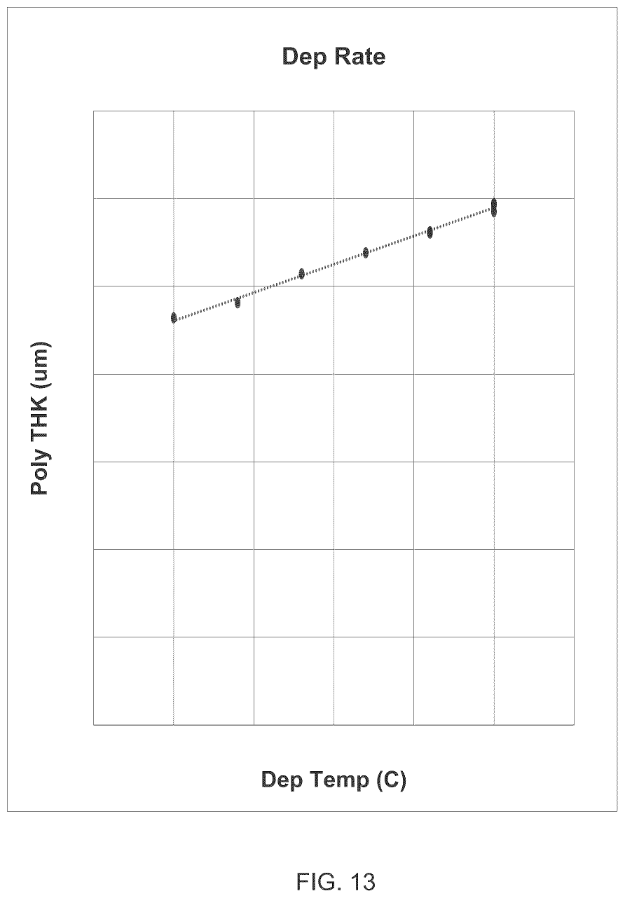

The offset values found in the first step for the pretreatment etch process step and the second process step for the high temperature steps (i.e., seed deposition, seed anneal, CTL deposition, and in-situ anneal) are used for the third step which requires correcting the overall process temperature for the high temperature steps. The temperature can shift due to normal process drift or due to variations in chamber parts or assembly that are within tolerance but still have an impact for carefully tuned processes like CTL deposition. In some instances, the temperature shift can be caused by thermocouple to wafer distance changes during maintenance or chamber to chamber variation. Measuring the temperature shift begins by processing test wafers using the deposition temperature and time prescribed by the predetermined recipe of the deposition process, and with the offset values found in the previous steps applied. The deposited layer thickness is measured using a KLA WaferSight series tool, but FTIR could also be used. The thickness of the deposited layer at the wafer center is compared to the target layer thickness of the recipe, and the temperature shift from recipe is calculated based on the deposition rate plot in FIG. 13. The target temperatures of the higher temperature steps (i.e., seed deposition, seed anneal, CTL deposition, and in-situ anneal) can then be adjusted to compensate for the temperature shift. For example, if it is determined that the deposited layer thickness is thicker than the target layer thickness by an amount that indicates the temperature is about 1-5° C. hotter than the recipe, then the target temperatures for the higher temperature steps can be adjusted to be about 1-5° C. colder in the recipe to compensate the temperature shift. The target temperature for the pretreatment process step can also be adjusted to compensate for this shift.

The fourth step of the process includes adjusting a duration of the deposition process based on the temperature shift and adjusted target temperature. The third step only matches the wafer center thickness. Due to the offset changes in the second step, the deposited layer thickness profile is expected to be slightly different from the recipe. So, the average deposited layer thickness would be slightly different from the recipe. After the temperature adjustment is set in the third step for the target temperatures of the higher temperature steps, a test wafer is processed and the average thickness of the deposited layer is measured. Based on the average thickness, the deposition duration can be adjusted to match the average deposited layer thickness with the recipe based on the deposition rate for the adjusted deposition temperature set in the third step.

The reactor apparatus is tuned and ready to process destructive test samples before releasing to production.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” “front,” back,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method of operating a reactor apparatus during a deposition process for depositing a layer of material on a semiconductor wafer, the deposition process including a first process step and a second process step, the method comprising:
controlling the reactor apparatus to initiate the deposition process;
receiving temperature feedback signals from temperature sensors positioned in respective zones of the reactor apparatus during the deposition process;
during the first process step:
applying a first set of offsets to the temperature feedback signals received from the temperature sensors, wherein the first set of offsets are predetermined to control a first characteristic of the semiconductor wafer following the first process step; and
transmitting first power instructions to heating devices each positioned in one of the zones of the reactor apparatus, wherein the first power instructions are determined by executing feedback control using the temperature feedback signals with the applied first set of offsets and a first target temperature; and
during the second process step:
applying a second set of offsets to the temperature feedback signals received from the temperature sensors, wherein the second set of offsets are predetermined to control a second characteristic of the semiconductor wafer following the second process step; and
transmitting second power instructions to the heating devices, wherein the second power instructions are determined by executing feedback control using the temperature feedback signals with the applied second set of offsets and a second target temperature.

2. The method of claim 1, wherein the first and second target temperatures are determined using target temperature setpoints of the respective first and second process steps according to a predetermined recipe of the deposition process, and at least the second target temperature is adjusted from the respective target temperature setpoint to control a third characteristic of the semiconductor wafer following the deposition process.

3. The method of claim 2, wherein the third characteristic is a thickness of the layer of material deposited on the semiconductor wafer.

4. The method of claim 1, wherein the first process step includes etching a surface layer of the semiconductor wafer and the second process step includes a deposition process step during which the layer of material is deposited on the etched surface layer of the semiconductor wafer.

5. The method of claim 4, wherein the first characteristic of the wafer is a thickness uniformity of the etched surface layer.

6. The method of claim 4, wherein the second characteristic is crystallographic slip in the semiconductor wafer.

7. The method of claim 1, wherein the second target temperature is greater than the first target temperature.

8. The method of claim 1, wherein the first target temperature is between 800° C. to 1100° C.

9. The method of claim 1, wherein the deposition process includes a third process step, and the method further comprises, during the third process step:
applying the second set of offsets to the temperature feedback signals received from the temperature sensors; and
transmitting the second power instructions to the heating devices determined by executing feedback control using the temperature feedback signals with the applied second set of offsets and a third target temperature.

10. The method of claim 9, wherein the second process step is a deposition process step and a third process step is an anneal step performed after the second process step.

11. The method of claim 10, wherein the third target temperature is greater than the second target temperature.

12. The method of claim 10, wherein the third target temperature is approximately equal to the second target temperature.

13. The method of claim 1, wherein the second set of offsets are different from the first set of offsets.

14. A system for depositing a layer of material on a semiconductor wafer, the system comprising:
a reactor apparatus including:
a chamber defining different zones;
a temperature sensor positioned in each zone;
a heating device positioned in each zone; and
a susceptor in the chamber for supporting the semiconductor wafer; and
a controller in communication with the reactor apparatus, the controller configured to:
store, in memory, a predetermined recipe for a deposition process including process steps, and target temperatures for the process steps of the deposition process;
control the reactor apparatus to initiate the deposition process according to the recipe;
receive temperature feedback signals from the temperature sensors of the reactor apparatus during the deposition process;
apply offsets stored in the memory to the temperature feedback signals received from the temperature sensors;
determine power instructions for the heating devices by executing feedback control using the temperature feedback signals with the applied offsets and the target temperatures; and
transmit the power instructions to the heating devices;
wherein the offsets stored in the memory include a first set of offsets applied during a first process step of the process steps and a second set of offsets applied during a second process step of the process steps, the first set of offsets being predetermined to control a first characteristic of the semiconductor wafer following the first process step and the second set of offsets being predetermined to control a second characteristic of the semiconductor wafer following the second process step.

15. The system of claim 14, wherein the target temperatures are determined using target temperature setpoints of the process steps according to the recipe and at least the target temperature of the second process step is adjusted from the respective target temperature setpoint to control a third characteristic of the semiconductor wafer following the deposition process.

16. The system of claim 15, wherein the third characteristic is a thickness of the layer of material deposited on the semiconductor wafer.

17. The system of claim 14, wherein the first process step includes etching a surface layer of the semiconductor wafer, and wherein the first characteristic of the wafer is a thickness uniformity of the etched surface layer.

18. The system of claim 14, wherein the second process step includes a deposition process step during which the layer of material is deposited on the semiconductor wafer, and wherein the second characteristic is crystallographic slip in the semiconductor wafer.

19. The system of claim 14, wherein the target temperature of the second process step is greater than the target temperature of the first process step.

20. The system of claim 14, wherein the target temperature of the first process step is between 800° C. to 1100° C., and the target temperature of the second process step is greater than 850° C.

21. The system claim 14, wherein the process steps of the deposition process include a third process step, and the controller is further configured to apply the second set of offsets to the temperature feedback signals during the third process step.

22. The system of claim 21, wherein the second process step is a deposition process step and a third process step is an anneal step performed after the second process step, and wherein the target temperature of the third process step is greater than the target temperature of the of second process step.

23. The system of claim 21, wherein the second process step is a deposition process step and a third process step is an anneal step performed after the second process step, and wherein the target temperature of the third process step is approximately equal to the target temperature of the of second process step.

24. The system of claim 14, wherein the second set of offsets are different from the first set of offsets.

25. A method of preparing a system for performing a deposition process for depositing a layer of material on a semiconductor wafer, the deposition process including a first process step and a second process step, the system including a controller and a reactor apparatus, the controller being configured to control operation of the reactor apparatus by receiving temperature feedback signals from the reactor apparatus, applying offsets to the temperature feedback signals, determining power instructions for heating devices of the reactor apparatus by executing feedback control using the temperature feedback signals with the applied offsets and a set of target temperatures including first and second target temperatures for the first and second process steps, respectively, and transmitting the power instructions to the heating devices, the method comprising:
performing the first process step of the deposition process on each of a first set of semiconductor wafers using the reactor apparatus, wherein the controller controls operation of the reactor apparatus during the first process step using a first set of offsets applied to the temperature feedback signals, wherein the first set of offsets is different for each of the first set of semiconductor wafers;
measuring a first characteristic of each of the first set of semiconductor wafers following the first process step;
identifying one of the first sets of offsets for use in controlling the reactor apparatus based on the measured first characteristics of the first set of semiconductor wafers;
performing the second process step of the deposition process on each of a second set of semiconductor wafers using the reactor apparatus, wherein the controller controls operation of the reactor apparatus during the second process step using a second set of offsets applied to the temperature feedback signals, wherein the second set of offsets is different for each of the second set of semiconductor wafers;
measuring a second characteristic of each of the second set of semiconductor wafers following the second process step;
identifying one of the second sets of offsets for use in controlling the reactor apparatus based on the measured second characteristics of the second set of semiconductor wafers; and
storing, in a memory of the controller, the identified first set of offsets for use in controlling the reactor apparatus during the first process step and the identified second set of offsets for use in controlling the reactor apparatus during the second process step.

26. The method of claim 25, further comprising performing the deposition process on a third set of semiconductor wafers, wherein the controller controls operation of the reactor apparatus during the first process step using the identified first set of offsets and operation of the reactor apparatus during the second process step using the identified second set of offsets.

27. The method of claim 26, wherein the controller controls operation of the deposition process using a different set of target temperatures for each of the third set of semiconductor wafers, the method further comprising:
measuring a third characteristic of each of the third set of semiconductor wafers following the deposition process;
identifying one of the sets of target temperatures for use in controlling the reactor apparatus based on the measured third characteristics of the third set of semiconductor wafers; and
storing, in a memory of the controller, the identified set of target temperatures for use in controlling the reactor apparatus during the deposition process.

28. The method of claim 27, further comprising performing the deposition process on a semiconductor wafer, wherein the controller controls operation of the reactor apparatus during the first process step using the identified first set of offsets, operation of the reactor apparatus during the second process step using the identified second set of offsets, and operation of the reactor apparatus during the deposition process using the identified set of target temperatures.

29. The method of claim 27, wherein the third characteristic is a thickness of the layer of material deposited on the semiconductor wafer.

30. The method of claim 25, wherein the first process step includes etching a surface layer of the semiconductor wafer and the second process step includes a deposition process step during which the layer of material is deposited on the etched surface layer of the semiconductor wafer.

31. The method of claim 30, wherein the first characteristic of the wafer is a thickness uniformity of the etched surface layer.

32. The method of claim 30, wherein the second characteristic is crystallographic slip in the semiconductor wafer.

33. The method of claim 25, wherein the second target temperature is greater than the first target temperature.

34. The method of claim 25, wherein the first target temperature is between 800° C. to 1100° C., and the second target temperature is greater than 850° C.

35. The method of claim 25, wherein the deposition process includes a third process step, and the method further comprises measuring the second characteristic of each of the second set of semiconductor wafers following the third process step.

36. The method of claim 35, wherein the second process step is a deposition process step and a third process step is an anneal step performed after the second process step.

37. The method of claim 36, wherein a third target temperature included in the set of target temperatures for the third process step is greater than the second target temperature.

38. The method of claim 36, wherein a third target temperature included in the set of target temperatures for the third process step is approximately equal to the second target temperature.

39. The method of claim 25, wherein the identified second set of offsets is different from the identified first set of offsets.
